(19) United States
(12) Patent Application Publication
(10) Pub. No.: US 2026/0327361 A1
(43) Pub. Date: Oct. 22, 2026

(54) RESIN COMPOSITION, ADHESIVE MEMBER, AND ELECTRONIC APPARATUS INCLUDING THE ADHESIVE MEMBER

(71) Applicant: Samsung Display Co., Ltd., Yongin-si (KR)

(72) Inventor: Koki IKUTA, Yokohama-shi (JP)

(21) Appl. No.: 19/643,501

(22) Filed: Apr. 9, 2026

(30) Foreign Application Priority Data
Apr. 17, 2025 (JP) 2025-067804

(51) Int. Cl. C08F 220/28; C08K 5/5425; C09D 11/38; C09J 4/00; C09J 11/06; C09J 133/14; H05K 5/03

(52) U.S. Cl. CPC C08F 220/281; C09D 11/38; C09J 4/00; C09J 11/06; C09J 133/14; H05K 5/03; C08F 2800/20; C08K 5/5425

(57) ABSTRACT

A resin composition, an adhesive member formed or made from the resin composition, and an electronic apparatus including the adhesive member are disclosed. The resin composition may include: a monofunctional (meth)acrylate monomer; a urethane (meth)acrylate oligomer; a first compound which does not include a double bond conjugated with a carbonyl group and includes at least one alkene group, the alkene group being a non-conjugated alkene group; and a photopolymerization initiator, wherein the content (e.g., amount) of the urethane (meth)acrylate oligomer is in the range of 1 wt % to 30 wt % based on a total of 100 wt % of the resin composition, a weight average molecular weight of the first compound is in the range of 28 g/mol to 2,500 g/mol, and the content (e.g., amount) of the first compound is in the range of 0.1 wt % to 15 wt % based on a total of 100 wt % of the resin composition.

### CROSS-REFERENCE TO RELATED APPLICATION

The present application claims priority to and the benefit of Japanese Patent Application No. 2025-067804, filed on Apr. 17, 2025, in the Japan Patent Office, the entire disclosure of which is incorporated herein by reference.

### BACKGROUND

### 1. Field

One or more embodiments of the present disclosure relate to a resin composition, an adhesive member formed or made from the resin composition, and an electronic apparatus including the adhesive member.

### 2. Description of the Related Art

Various display devices for use in multimedia apparatuses, such as televisions, mobile phones, tablet computers, navigation systems, and game consoles, are being developed. The display devices include various components constituting the display devices, and adhesive members are provided between the components constituting the display devices. The adhesive members may be formed or prepared by providing a resin composition, and it is desirable for the adhesive members included in the display devices to have the characteristics of stably or suitably bonding the components of the display devices, while not degrading display quality.

### SUMMARY

One or more aspects of embodiments of the present disclosure are directed toward a resin composition that exhibits low viscosity before curing and high adhesive strength and excellent or suitable light resistance after curing.

One or more aspects of embodiments of the present disclosure are directed toward an adhesive member that exhibits excellent or suitable adhesive reliability and excellent or suitable light resistance.

One or more aspects of embodiments of the present disclosure are directed toward an electronic apparatus that exhibits excellent or suitable reliability and excellent or suitable display quality.

Additional aspects of embodiments will be set forth in part in the description which follows and, in part, will be apparent from the description or may be learned by practice of the presented embodiments of the disclosure.

One or more embodiments of the present disclosure provide a resin composition including: a monofunctional (meth)acrylate monomer; a urethane (meth)acrylate oligomer; a first compound which does not include a double bond (e.g., a carbon-carbon double bond, a carbon-nitrogen double bond, a carbon-oxygen double bond, a nitrogen-oxygen double bond, and/or the like) conjugated with a carbonyl group and includes at least one alkene group, the alkene group being a non-conjugated alkene group; and a photopolymerization initiator (e.g., a photoinitiator), wherein the content (e.g., amount) of the urethane (meth)acrylate oligomer is in the range of about 1 wt % to about 30 wt % based on a total of 100 wt % of the resin composition, a weight average molecular weight of the first compound is in the range of about 28 g/mol to about 2,500 g/mol, and the content (e.g., amount) of the first compound is in the range of about 0.1 wt % to about 15 wt % based on a total of 100 wt % of the resin composition.

A shear viscosity as measured by a JIS Z 8803 method at about 30 °C may be in the range of about 8 mPa·s to about 50 mPa·s.

The first compound may include at least one selected from among pinene derivatives, rosin derivatives, polybutadiene, limonene, cholesterol derivatives, and diprenyl glycerin ether.

The pinene derivative may include at least one selected from among (1S)-(−)-α-pinene and α-terpineol.

The rosin derivative may include dihydroabietic acid.

The monofunctional (meth)acrylate monomer may include at least one selected from among 4-hydroxybutyl acrylate, tetrahydrofurfuryl acrylate, dodecyl acrylate, 2-methoxyethyl acrylate, ethyl acrylate, isobornyl acrylate, and isodecyl acrylate.

The content (e.g., amount) of the monofunctional (meth)acrylate monomer may be in the range of about 67 wt % to about 95 wt % based on a total of 100 wt % of the resin composition.

A weight average molecular weight of the urethane (meth)acrylate oligomer may be in the range of about 3,000 g/mol to about 50,000 g/mol.

The resin composition may further include a silane coupling agent.

A yellowness index measured immediately after photocuring under conditions of integrated ultraviolet (UV) radiation dose in the atmosphere in the range of about 1600 mJ/cm² to about 2000 mJ/cm² may be in the range of about 0.1 to about 1.5.

After photocuring, a yellowness index measured after exposure for about 120 hours under conditions of about 0.4 W/m² of a light intensity at about 340 nm and about 50 °C using a xenon arc lamp may be in the range of about 0.1 to about 1.5.

A difference between a yellowness index measured immediately after photocuring under conditions of integrated UV radiation dose in the atmosphere in the range of about 1600 mJ/cm² to about 2000 mJ/cm² and a yellowness index measured after the photocuring and after exposure for about 120 hours under conditions of about 0.4 W/m² of a light intensity at about 340 nm and about 50 °C using a xenon arc lamp may be in the range of about −1.0 to about 1.0.

The resin composition may be provided by an inkjet printing method and/or a dispensing method.

One or more embodiments of the present disclosure provide an adhesive member including a polymer derived from a resin composition, wherein the resin composition includes: a monofunctional (meth)acrylate monomer; a urethane (meth)acrylate oligomer; a first compound which does not include a double bond (e.g., a carbon-carbon double bond, a carbon-nitrogen double bond, a carbon-oxygen double bond, a nitrogen-oxygen double bond, and/or the like) conjugated with a carbonyl group and includes at least one alkene group, the alkene group being a non-conjugated alkene group; and a photopolymerization initiator (e.g., a photoinitiator), the content (e.g., amount) of the urethane (meth)acrylate oligomer is in the range of about 1 wt % to about 30 wt % based on a total of 100 wt % of the resin composition, a weight average molecular weight of the first compound is in the range of about 28 g/mol to about 2,500 g/mol, and the content (e.g., amount) of the first compound is in the range of about 0.1 wt % to about 15 wt % based on a total of 100 wt % of the resin composition.

A shear viscosity as measured by a JIS Z 8803 method at about 30 °C may be in the range of about 8 mPa·s to about 50 mPa·s.

Three-point bending strength measured at about 30 °C may be in the range of about 35 N to about 60 N.

One or more embodiments of the present disclosure provide an electronic apparatus including a display device to provide images, and at least one adhesive member included in the display device and including a polymer derived from a resin composition, wherein the resin composition includes: a monofunctional (meth)acrylate monomer; a urethane (meth)acrylate oligomer; a first compound which does not include a double bond (e.g., a carbon-carbon double bond, a carbon-nitrogen double bond, a carbon-oxygen double bond, a nitrogen-oxygen double bond, and/or the like) conjugated with a carbonyl group and includes at least one alkene group, the alkene group being a non-conjugated alkene group; and a photopolymerization initiator (e.g., a photoinitiator), the content (e.g., amount) of the urethane (meth)acrylate oligomer is in the range of about 1 wt % to about 30 wt % based on a total of 100 wt % of the resin composition, a weight average molecular weight of the first compound is in the range of about 28 g/mol to about 2,500 g/mol, and the content (e.g., amount) of the first compound is in the range of about 0.1 wt % to about 15 wt % based on a total of 100 wt % of the resin composition.

The display device may include a display module and a window, and the adhesive member may be provided between the display module and the window.

The window may include a base layer and a printed layer provided between the adhesive member and the base layer, and the resin composition provided on one side of the display module or one side of the window may be cured by light transmitted through the printed layer to form or provide the adhesive member.

The display device may include a display module, a processor, a memory, and a power module.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a block diagram of an electronic apparatus according to one or more embodiments;

FIG. 2 illustrates schematic diagrams of electronic apparatuses according to one or more embodiments;

FIG. 3 is a perspective view illustrating an electronic apparatus of one or more embodiments;

FIG. 4 is an exploded perspective view illustrating a display device according to one or more embodiments;

FIG. 5 is a cross-sectional view illustrating a portion corresponding to the line I-I′ in FIG. 4;

FIG. 6 is a cross-sectional view illustrating a portion of a display device of one or more embodiments;

FIG. 7A is a diagram illustrating a manufacturing method of an adhesive member of one or more embodiments;

FIG. 7B is a diagram illustrating a manufacturing method of an adhesive member of one or more embodiments;

FIG. 7C is a diagram illustrating a manufacturing method of an adhesive member of one or more embodiments;

FIG. 7D is a diagram illustrating a manufacturing method of an adhesive member of one or more embodiments;

FIG. 8A is a diagram illustrating a manufacturing method of an adhesive member of one or more embodiments;

FIG. 8B is a diagram illustrating a manufacturing method of an adhesive member of one or more embodiments;

FIG. 8C is a diagram illustrating a manufacturing method of an adhesive member of one or more embodiments;

FIG. 9 is a cross-sectional view illustrating a display device of one or more embodiments; and

FIG. 10 is a cross-sectional view illustrating a display device of one or more embodiments.

### DETAILED DESCRIPTION

The subject matter of the present disclosure may be modified in one or more suitable alternate forms, and thus example embodiments will be illustrated in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

In the present disclosure, it will be understood that if (e.g., when) an element (or a region, a layer, a portion, and/or the like) is referred to as being “on,” “connected to,” or “coupled to” another element, it may be directly on, directly connected to, or directly coupled to the other element, or other elements may be present therebetween.

In contrast, if (e.g., when) an element is referred to as being “directly on” or “directly above” another element, there are no intervening elements present therebetween.

Like reference numerals or symbols refer to like elements throughout the attached drawings and the written description, and duplicative descriptions thereof may not be provided in the specification.

In the drawings, the thickness, ratio, and size of the elements may be exaggerated for effectively describing the technical contents.

As used herein, the term “and/or” or “or” includes any and all combinations of one or more of the associated listed elements.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As used herein, “combination thereof” may refer to a mixture, a stack, a composite, a copolymer, an alloy, a blend, a reaction product, and/or the like of constituents.

It will be understood that, although the terms “first,” “second,” and/or the like may be used herein to describe one or more suitable elements, the elements are not to be limited by these terms. These terms are only used to distinguish one element, component, region, layer, or section from another element, component, region, layer, or section. For instance, a first element, component, region, layer, or section described herein may be termed a second element, component, region, layer, or section without departing from the scope of the present disclosure. Similarly, a second element, component, region, layer, or section may be termed a first element, component, region, layer, or section.

In the present disclosure, the singular expressions “a,” “an,” and “the” are intended to include the plural forms as well, unless the context clearly indicates otherwise.

The terms “below,” “under,” “on the lower side,” “above,” “over,” “on the upper side,” and/or the like may be used to describe the relationships between the elements illustrated in the drawings. These terms are relative concepts and are described on the basis of the directions indicated in the drawings.

It will be further understood that the terms “comprises,” “includes,” “has,” “comprising,” “including,” and/or “having,” if (e.g., when) used in the present disclosure, specify the presence of stated features, numbers, steps, methods, operations, elements, components, or combinations thereof, but do not preclude the possibility of the presence or addition of one or more other features, numbers, steps, methods, operations, elements, components, and/or combinations thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a 1 range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

Unless otherwise defined, all terms (including technical and scientific terms) used herein have substantially the same meaning as generally understood by one of ordinary skill in the art to which the present disclosure belongs. It will be further understood that terms, such as those defined in generally-used dictionaries, should be interpreted as having a meaning that is consistent with their meaning in the context of the relevant art and will not be interpreted in an idealized or overly formal sense unless expressly so defined herein.

Hereinafter, a resin composition according to one or more embodiments of the present disclosure, an adhesive member according to one or more embodiments, and an electronic apparatus including the adhesive member will be described in more detail. A display device according to one or more embodiments may be applied to one or more suitable electronic apparatuses. The electronic apparatus according to one or more embodiments may include a display device and may further include a module or a device having additional functions in addition to the display device.

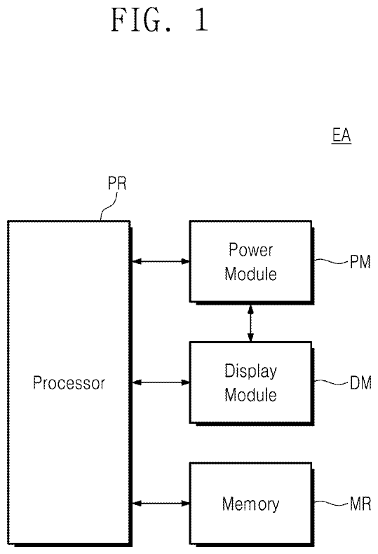

FIG. 1 is a block diagram of an electronic apparatus according to one or more embodiments. Referring to FIG. 1, an electronic apparatus EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information for the operation of the processor PR or the display module DM. If (e.g., when) the processor PR executes an application stored in the memory MR, image data signals and/or input control signals may be transmitted to the display module DM, and the display module DM may process the received signals and output image information through a display screen.

The power module PM may include a power supply module, such as a power adapter or battery, and a power conversion module that converts the power supplied by the power supply module to generate power for the operation of the electronic apparatus EA.

At least one selected from among the components of the electronic apparatus EA may be included in a display device according to one or more embodiments. In one or more embodiments, one or more of the individual modules functionally included within a single module may be included within the display device, while others may be provided separately from the display device. For example, the display device may include the display module DM, and the processor PR, memory MR, and power module PM may be provided as separate components within the electronic apparatus EA rather than the display device.

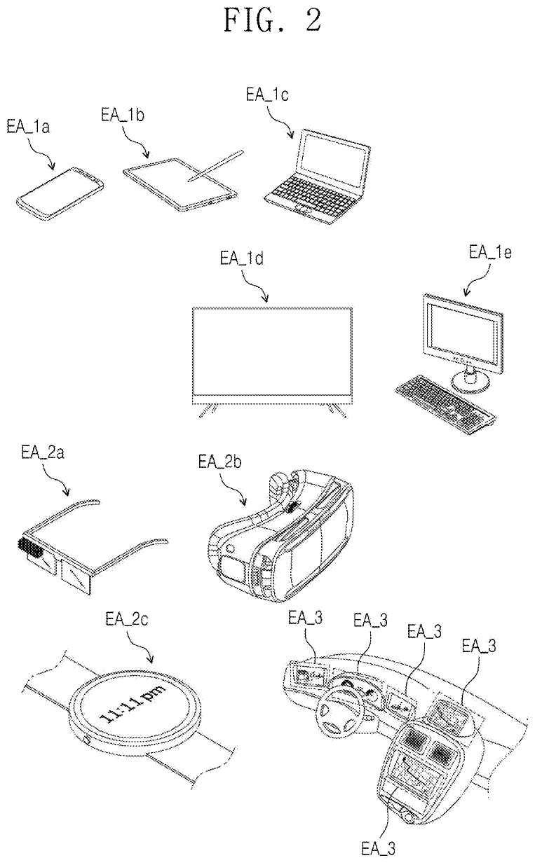

FIG. 2 illustrates schematic diagrams of electronic apparatuses according to one or more embodiments. Referring to FIG. 2, an electronic apparatus in which the display device according to one or more embodiments is applied to, may include not only image display electronic apparatuses, such as a smart phone EA_1a, a tablet PC EA_1b, a laptop EA_1c, a TV EA_1d, and a desk monitor (EA_1e), but also wearable electronic apparatuses including display modules, such as smart glasses EA_2a, a head-mounted display EA_2b, and a smart watch EA_2c, and a vehicle electronic apparatus EA_3 including display modules, such as an instrument panel, a center fascia, a center information display (CID) provided on a dashboard and a room mirror display of a vehicle.

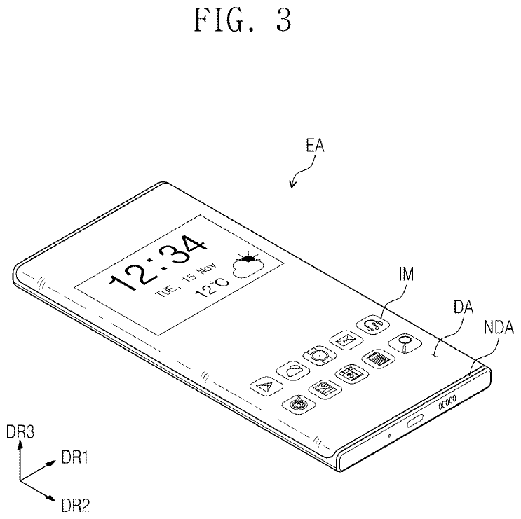

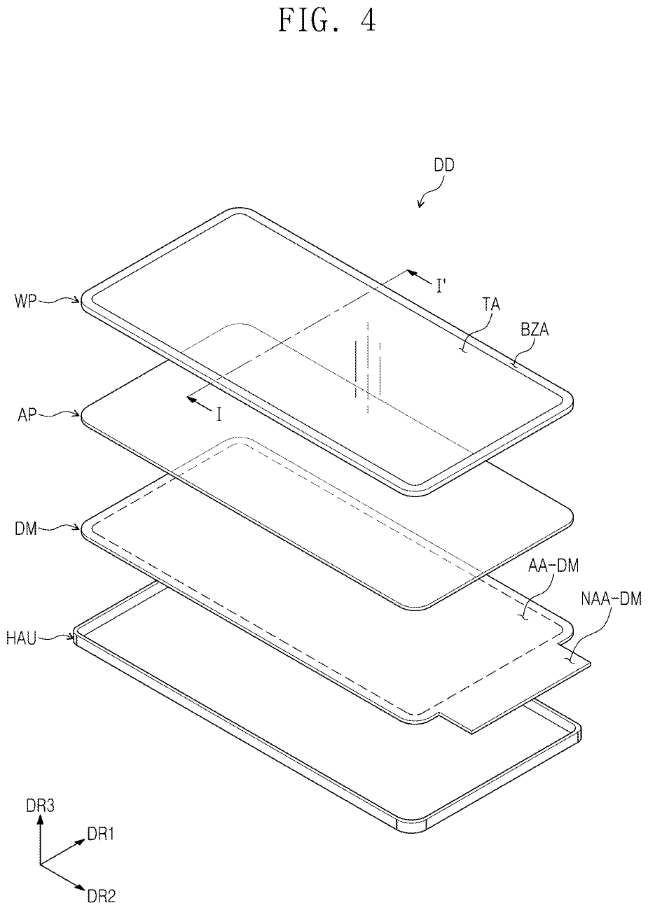

FIG. 3 is a perspective view of an electronic apparatus of one or more embodiments. FIG. 4 is an exploded perspective view of a display device according to one or more embodiments.

An electronic apparatus EA of one or more embodiments, as illustrated in FIG. 3, may be an apparatus activated by an electrical signal. In FIG. 3, a smartphone is illustrated as an example of the electronic apparatus EA.

The electronic apparatus EA according to one or more embodiments may display an image IM through a display area DA. The display area DA may include a plane defined by a first direction axis DR1 and a second direction axis DR2. The display area DA may include a curved surface bent from at least one side of the plane defined by the first direction axis DR1 and the second direction axis DR2. The electronic apparatus EA according to one or more embodiments, as illustrated in FIG. 3, may include two curved surfaces each bent from two sides of the plane defined by the first direction axis DR1 and the second direction axis DR2. However, the shape of the display area DA is not limited thereto. For example, the display area DA may include only the plane defined by the first direction axis DR1 and the second direction axis DR2, or the display area DA may further include at least two or more, for example, four curved surfaces each bent from four sides of the plane defined by the first direction axis DR1 and the second direction axis DR2.

The electronic apparatus EA of one or more embodiments may be flexible. “Flexible” refers to the property of being bendable and may include a structure ranging from a completely (e.g., almost completely) foldable structure to a structure that may be bent to a degree of several nanometers. For example, the electronic apparatus EA 1 may be a foldable electronic apparatus. Furthermore, the electronic apparatus EA may be rigid.

The non-display area NDA may be an area adjacent to the display area DA. The non-display area NDA may be around (e.g., surround) the display area DA. Accordingly, the shape of the display area DA may be substantially defined by the non-display area NDA. However, this is an example, and the non-display area NDA may be provided adjacent to only one side of the display area DA or may not be provided. The display area DA may be provided in one or more suitable shapes and is not limited thereto.

In FIG. 3 and the following drawings, the first direction axis DR1 to the third direction axis DR3 are illustrated, and the directions indicated by the first to third direction axes DR1, DR2, and DR3, described herein are relative concepts and may be converted to other directions. In one or more embodiments, the directions indicated by the first to third direction axes DR1, DR2, and DR3 may be described as the first to third directions, and the same drawing reference symbols may be used. In one or more embodiments, the first direction axis DR1 and the second direction axis DR2 may be orthogonal to each other, and the third direction axis DR3 may be a normal direction to the plane defined by the first direction axis DR1 and the second direction axis DR2.

The thickness direction of the electronic apparatus EA may be substantially parallel to the third direction axis DR3, which is a normal direction to the plane defined by the first direction axis DR1 and the second direction axis DR2. In one or more embodiments, the front (e.g., top surface, upper surface, or upper side) and back (e.g., bottom surface, lower surface, or lower side) of the members constituting the electronic apparatus EA may be defined based on the third direction axis DR3. In one or more embodiments, the direction in which the third direction axis DR3 extends may be substantially parallel to the thickness direction, and the front (e.g., top surface, upper surface, or upper side) refers to a surface (or direction) adjacent to the surface on which the image IM is displayed, and the back (or bottom surface, lower surface, lower side) refers to a surface (or direction) spaced from the surface on which the image IM is displayed. In one or more embodiments, a plane refers to a surface substantially parallel to a plane defined by the first direction axis DR1 and the second direction axis DR2, and a cross-section refers to a surface that is normal (e.g., substantially perpendicular) to the plane defined by the first direction axis DR1 and the second direction axis DR2 and substantially parallel to the thickness direction DR3.

FIG. 4 is an exploded perspective view of a display device according to one or more embodiments. The display device DD according to one or more embodiments, as illustrated in FIG. 4, may be included in the electronic apparatus EA according to one or more embodiments, as illustrated in FIG. 3.

Referring to FIG. 4, the display device DD according to one or more embodiments may include a display module DM, a window WP provided on the display module DM, and an adhesive member AP provided between the display module DM and the window WP. In one or more embodiments, the display device DD may further include a housing HAU in which the display module DM is accommodated.

In the display device DD illustrated in FIG. 4, the window WP and the housing HAU may be combined to constitute the exterior of the display device DD. The housing HAU may be provided below the display module DM. The housing HAU may include a material having relatively or substantially high rigidity. For example, the housing HAU may include a plurality of frames and/or plates composed of glass, plastic, and/or metal. The housing HAU may provide accommodation space. The display module DM may be accommodated within the accommodation space and protected from external impact.

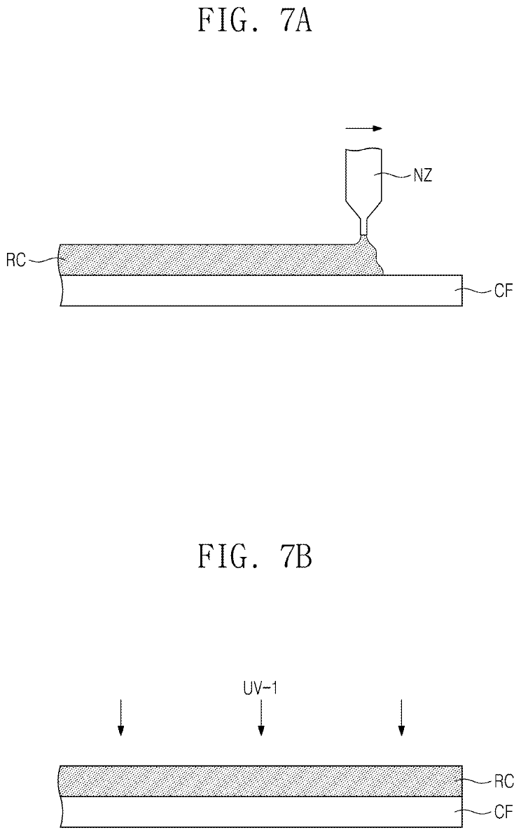

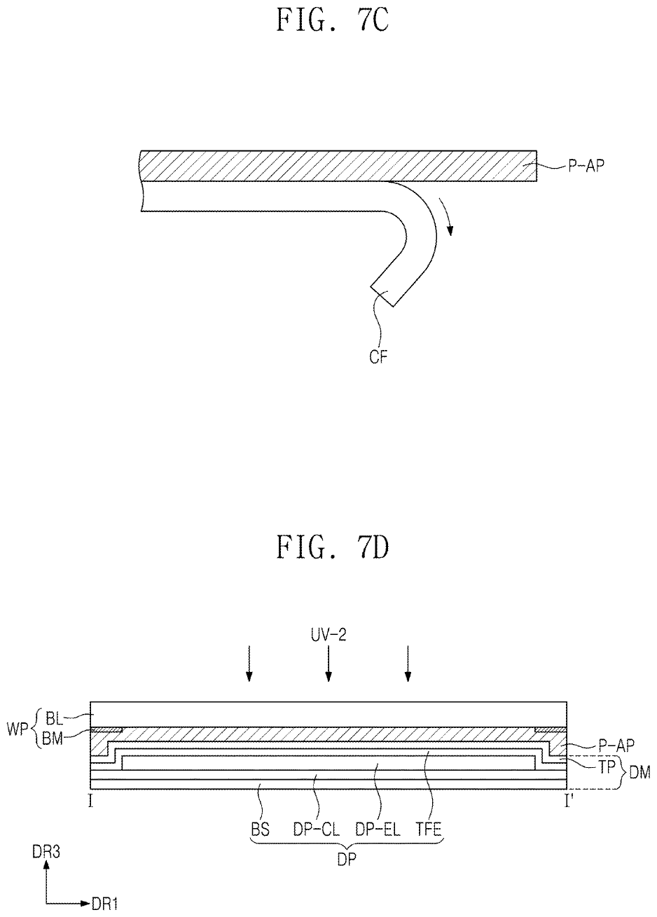

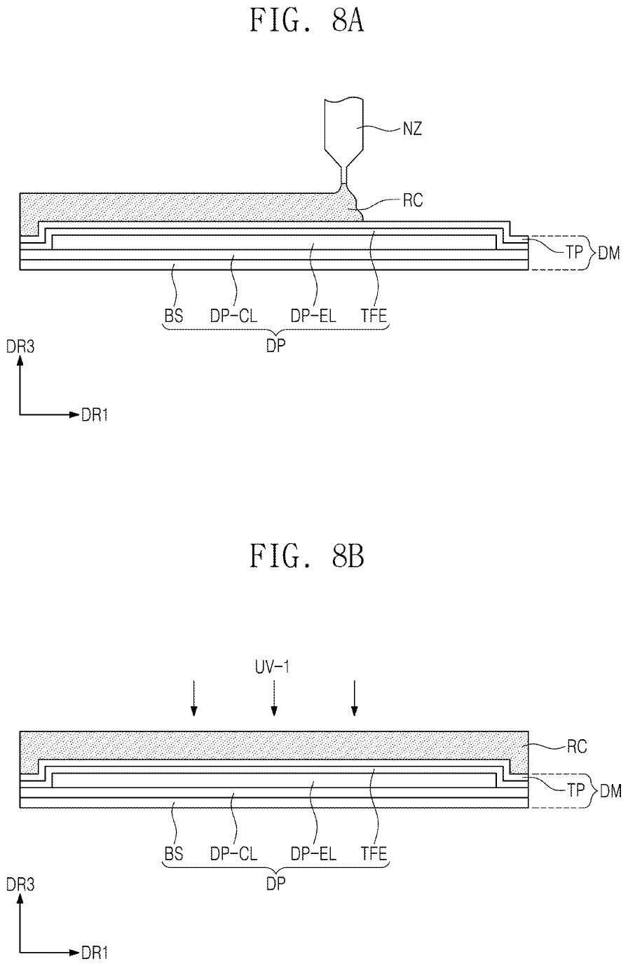

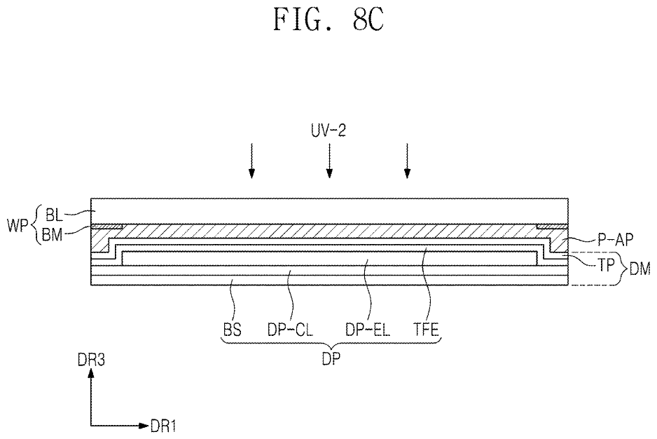

In one or more embodiments, the adhesive member AP may include a polymer derived from a resin composition RC (FIGS. 7A and 8A). The adhesive member AP may be formed or provided by photocuring the resin composition RC (FIGS. 7A and 8A). The display module DM and the window WP may be bonded by the adhesive member AP. The adhesive member AP of one or more embodiments may be formed or made from the resin composition RC (FIGS. 7A and 8A) and exhibit excellent or suitable bonding reliability. In one or more embodiments, the adhesive member AP may be prevented from discoloration due to external light (for example, ultraviolet rays).

The window WP may include a transmissive area TA and a bezel area BZA. The transmissive area TA may overlap at least a portion of the active area AA-DM of the display module DM. The transmissive area TA may be an optically transparent (e.g., substantially transparent) area. An image IM (FIG. 3) may be provided to a user through the transmissive area TA.

The bezel area BZA may be an area having relatively low light transmittance compared to the transmissive area TA. The bezel area BZA may define the shape of the transmissive area TA. The bezel area BZA may be adjacent to the transmissive area TA and may be around (e.g., surround) the transmissive area TA.

The bezel area BZA may have a color. The bezel area BZA may cover the peripheral area NAA-DM of the display module DM to block the peripheral area NAA-DM from being recognized from the outside. However, embodiments of the present disclosure are not limited thereto, and the bezel area BZA may be provided adjacent to only one side of the transmissive area TA, or at least a portion of the bezel area BZA may not be provided.

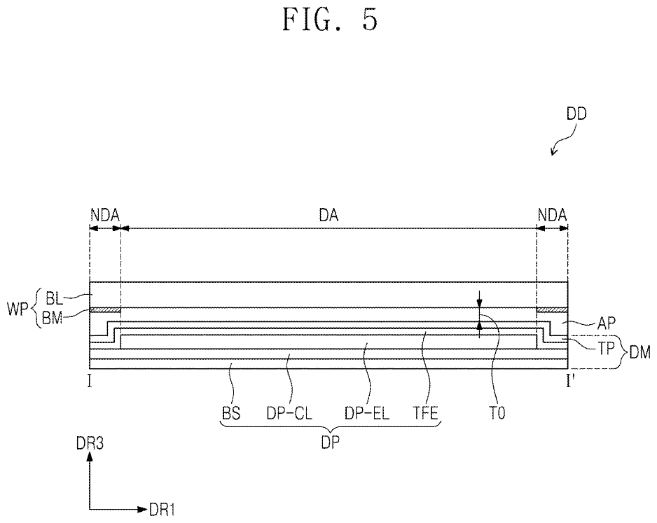

FIG. 5 is a cross-sectional view illustrating a portion corresponding to the line I-l′ of FIG. 4. FIG. 5 is a cross-sectional view of a display device according to one or more embodiments, including a display module DM, an adhesive member AP, and a window WP of FIG. 4.

Referring to FIG. 5, the display module DM may include a display panel DP and an input detection part TP provided on the display panel DP. The display panel DP may have a configuration or arrangement that substantially generates an image. The display panel DP may include a base substrate BS, a circuit layer DP-CL provided on the base substrate BS, a display element layer DP-EL provided on the circuit layer DP-CL, and an encapsulation layer TFE covering the display element layer DP-EL. An adhesive member AP may be provided between the display module DM and the window WP. If (e.g., when) a display module DM includes a display panel DP and an input detection part TP, an adhesive member AP may be provided between the input detection part TP and the window WP, provided on the display panel DP.

The configuration or arrangement of the display panel DP illustrated in FIG. 5 and/or the like is an example, and embodiments of the present disclosure are not limited thereto. For example, the display panel DP may include a liquid crystal display, and in this case, the encapsulation layer TFE may not be provided.

The base substrate BS may provide a base surface on which the circuit layer DP-CL is provided. The base substrate BS may be a flexible substrate capable of bending, folding, or rolling. The base substrate BS may be a glass substrate, a metal substrate, and/or a polymer substrate. However, embodiments of the present disclosure are not limited thereto, and the base substrate BS may include an inorganic layer, an organic layer, or a composite material layer.

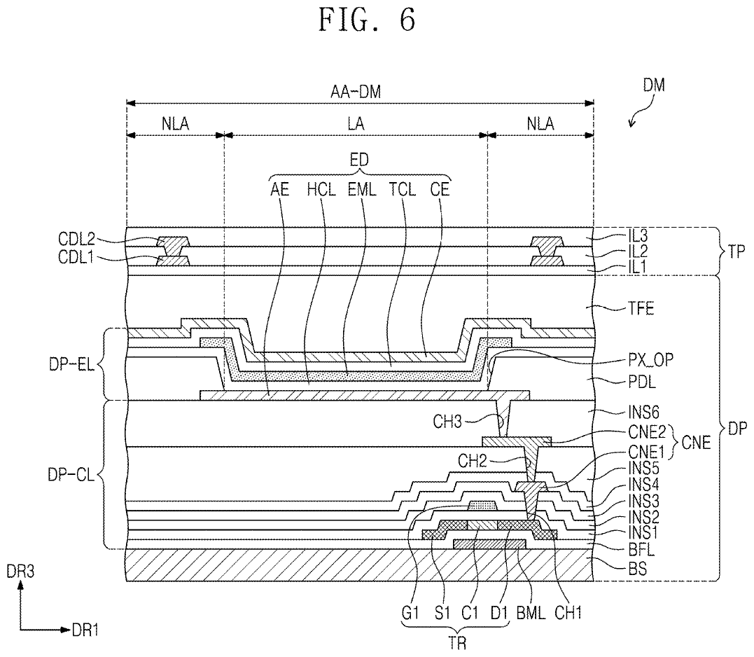

The circuit layer DP-CL may include an insulating (e.g., electrically insulating) layer, a semiconductor pattern, a conductive (e.g., electrically conductive) pattern, a signal line, and/or the like. For example, the circuit layer DP-CL may include a switching transistor and a driving transistor to drive a light emitting element ED (FIG. 6) of a display element layer DP-EL, described herein.

The display element layer DP-EL may include a light emitting element ED (FIG. 6) that emits light. For example, the light emitting element ED (FIG. 6) may include an organic light emitting material, an inorganic light emitting material, an organic-inorganic light emitting material, a quantum dot, a quantum rod, a micro light-emitting diode (LED), and/or a nano LED.

An encapsulation layer TFE may be provided on the display element layer DP-EL. The encapsulation layer TFE may protect the display element layer DP-EL from foreign substances, such as moisture, oxygen, and/or dust particles. The encapsulation layer TFE may include at least one inorganic layer. For example, the encapsulation layer TFE may include an inorganic layer, an organic layer, and an inorganic layer, sequentially stacked.

The input detection part TP may be provided on the display panel DP. For example, the input detection part TP may be provided directly on the encapsulation layer TFE of the display panel DP. In one or more embodiments, an adhesive layer may be provided between the input detection part TP and the display panel DP.

In the present disclosure, one element being directly on another element refers to that no third element is between the two elements. For example, one element being “directly on” another element refers to that the two elements are in “contact.”

The input detection part TP may detect an external input, convert the external input into an input signal, and provide the input signal to the display panel DP. For example, in the display device DD of one or more embodiments, the input detection part TP may be a touch detection part that detects touch. The input detection part TP may recognize a direct user touch, an indirect user touch, a direct object touch, or an indirect object touch.

The input detection part TP may detect at least one of the position or the intensity (pressure) of an externally applied touch. In one or more embodiments, the input detection part TP may have one or more suitable structures or be composed of one or more suitable materials, but embodiments of the present disclosure are not limited thereto. For example, the input detection part TP may sense an external input using electrostatic capacitance. The display panel DP may receive an input signal from the input detection part TP and generate an image corresponding to the input signal.

The window WP may include a base layer BL and a printed layer BM. In one or more embodiments, the window WP may further include at least one functional layer provided on the base layer BL. For example, the functional layer may be a hard coating layer, an anti-fingerprint coating layer, and/or the like, but embodiments of the present disclosure are not limited thereto.

The base layer BL may be a glass substrate. In one or more embodiments, the base layer BL may be a plastic substrate. For example, the base layer BL may be made or composed of polyimide, polyacrylate, polymethylmethacrylate, polycarbonate, polyethylene naphthalate, polyvinylidene chloride, polyvinylidene difluoride, polystyrene, an ethylene vinyl alcohol copolymer, or a combination thereof.

The printed layer BM may be provided on one surface of the base layer BL. The printed layer BM may be provided on the lower surface of the base layer BL adjacent to the display module DM. The printed layer BM may be provided in an edge region of the base layer BL. The printed layer BM may be an ink-printed layer. In one or more embodiments, the printed layer BM may be a layer formed or provided by including a pigment and/or a dye. The printed layer BM may be formed or provided by including a light absorbing material or by including a black pigment and/or a black dye. However, this is an example, and embodiments of the present disclosure are not limited thereto. In the window WP, the bezel area BZA (FIG. 4) may be a portion where the printed layer BM is provided.

The thickness T0 of the adhesive member AP may be in the range of about 50 μm to about 300 μm. For example, the adhesive member AP may have a thickness T0 in the range of about 50 μm to about 250 μm. However, this is an example, and the thickness T0 of the adhesive member AP is not limited thereto.

FIG. 6 is a cross-sectional view illustrating the display module DM of FIG. 5. The configuration or arrangement of the display module DM illustrated in FIG. 6 is an example, and embodiments of the present disclosure are not limited thereto.

In FIG. 6, the base substrate BS may include a single layer or two or more layers. For example, the base substrate BS may include a first synthetic resin layer, a single or multilayer inorganic layer, and a second synthetic resin layer provided on the single or multilayer inorganic layer. Each of the first synthetic resin layer and the second synthetic resin layer may include a polyimide-based resin. In one or more embodiments, each of the first synthetic resin layer and the second synthetic resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin. In the present disclosure, the “~~-based” resin refers to one that includes a functional group of “~~.”

The display panel DP may include a transistor TR and a light emitting element ED. The transistor TR and the light emitting element ED may be provided on a base substrate BS. Although one transistor TR is illustrated in FIG. 6, the display panel DP may include a plurality of transistors and at least one capacitor to drive the light emitting element ED.

A circuit layer DP-CL may be provided on the base substrate BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL illustrated in FIG. 6 is an example, and the stacked structure of the circuit layer DP-CL may vary depending on the configuration or arrangement of a display panel DP and the process of the circuit layer DP-CL.

The shielding electrode BML may be provided on the base substrate BS. The shielding electrode BML may overlap the transistor TR. The shielding electrode BML may protect the transistor TR by blocking light incident (or by reducing a degree or occurrence of light incident) on the transistor TR from the lower part of the display panel DP. The shielding electrode BML may include a conductive (e.g., electrically conductive) material. If (e.g., when) a voltage is applied to the shielding electrode BML, the threshold voltage of the transistor TR provided on the shielding electrode BML may be maintained. However, embodiments of the present disclosure are not limited thereto, and the shielding electrode BML may be a floating electrode. The shielding electrode BML may not be provided.

The buffer layer BFL may be provided on the base substrate BS to cover the shielding electrode BML. The buffer layer BFL may include an inorganic layer. The buffer layer BFL may improve or enhance bonding strength between a semiconductor pattern or a conductive (e.g., electrically conductive) pattern provided on the buffer layer BFL and the base substrate BS.

The transistor TR may include a source S1, a channel C1, a drain D1, and a gate G1. The source S1, the channel C1, and the drain D1 of the transistor TR may be provided from a semiconductor pattern. The semiconductor pattern of the transistor TR may include polysilicon, amorphous (e.g., non-crystalline) silicon, and/or metal oxide, and any semiconductor material having suitable semiconductor properties may be applied without limitation and is not limited to any one material.

The semiconductor pattern may include two or more regions differentiated by conductivity (e.g., electrical conductivity) magnitude. Regions within the semiconductor pattern doped with dopants or having reduced metal oxides may have high conductivity (e.g., electrical conductivity) and may substantially function as source and drain electrodes of the transistor TR. Regions within the semiconductor pattern with high conductivity (e.g., electrical conductivity) may correspond to the source S1 1 and drain D1 of the transistor TR. Regions within the semiconductor pattern that are undoped or lightly doped, or have non-reduced metal oxides and thus have low conductivity (e.g., electrical conductivity), may correspond to the channel C1 (or active) of the transistor TR.

The first insulating layer INS1 may cover the semiconductor pattern of the transistor TR and may be provided on the buffer layer BFL. The gate G1 of the transistor TR may be provided on the first insulating layer INS1. On a plane, the gate G1 may overlap the channel C1 of the transistor TR. The gate G1 may function as a mask in a process of doping the semiconductor pattern of the transistor TR.

The second insulating layer INS2 may cover the gate G1 and be provided on the first insulating layer INS1. The third insulating layer INS3 may be provided on the second insulating layer INS2.

The connection electrode CNE may include a first connection electrode CNE1 and a second connection electrode CNE2 to electrically connect the transistor TR and the light emitting element ED. However, the configuration or arrangement of the connection electrode CNE to electrically connect the transistor TR and the light emitting element ED is not limited thereto, and one of the first and second connection electrodes CNE1 and CNE2 may not be provided, or an additional connection electrode may be included.

The first connection electrode CNE1 may be provided on the third insulating layer INS3. The first connection electrode CNE1 may be connected to the drain D1 through a first contact hole CH1 penetrating the first to third insulating layers INS1 to INS3. The fourth insulating layer INS4 may cover the first connection electrode CNE1 and be provided on the third insulating layer INS3. The fifth insulating layer INS5 may be provided on the fourth insulating layer INS4.

The second connection electrode CNE2 may be provided on the fifth insulating layer INS5. The second connection electrode CNE2 may be connected to the first connection electrode CNE1 through a second contact hole CH2 penetrating the fourth and fifth insulating layers INS4 and INS5. The sixth insulating layer INS6 may cover the second connection electrode CNE2 and be provided on the fifth insulating layer INS5.

Each of the first to sixth insulating layers INS1 to INS6 may include an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel defining layer PDL and a light emitting element ED. The light emitting element ED may include a first electrode AE, a hole control layer HCL, a light emitting layer EML, an electron control layer TCL, and a second electrode CE.

The first electrode AE may be provided on the sixth insulating layer INS6. The first electrode AE may be connected to the second connection electrode CNE2 through a third contact hole CH3 penetrating the sixth insulating layer INS6. The first electrode (AE) may be electrically connected to the drain D1 of the transistor TR through the first and second connection electrodes CNE1 and CNE2.

The first electrode AE may be formed or composed of a metal material, a metal alloy, or a conductive (e.g., electrically conductive) compound. The first electrode AE may be an anode or a cathode. In one or more embodiments, the first electrode AE may be a pixel electrode. The first electrode AE may be a transmissive electrode, a transflective electrode, or a reflective electrode. The first electrode AE may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode AE is a transparent (e.g., substantially transparent) electrode, the first electrode AE may include a transparent (e.g., substantially transparent) metal oxide, for example, indium tin oxide (ITO), indium zinc oxide (IZO), zinc oxide (ZnO), and/or indium tin zinc oxide (ITZO). If (e.g., when) the first electrode AE is a transflective electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). In one or more embodiments, the first electrode AE may have a multilayer structure including a reflective film or a transflective film formed or composed of the materials as described herein and a transparent (e.g., substantially transparent) conductive (e.g., electrically conductive) film formed or composed of indium tin oxide (ITO), indium zinc oxide (IZO), zinc oxide (ZnO), indium tin zinc oxide (ITZO), and/or the like. For example, the first electrode AE may have a three-layer structure of ITO/Ag/ITO, without limitation. Also, embodiments of the present disclosure are not limited thereto, but the first electrode AE may include the metal material as described herein, a combination of two or more metal materials selected from among the metal materials as described herein, or an oxide of the metal materials as described herein.

The pixel defining layer PDL may be provided on the sixth insulating layer INS6. The pixel defining layer PDL may be formed or composed of a polymer resin. For example, the pixel defining layer PDL may be formed or provided by including a polyacrylate-based resin and/or a polyimide-based resin. In one or more embodiments, the pixel defining layer PDL may be formed or provided by further including an inorganic material in addition to the polymer resin. The pixel defining layer PDL may be formed or provided by including a light absorbing material or may be formed or provided by including a black pigment and/or a black dye. The pixel defining layer PDL formed or provided by including a black pigment and/or a black dye may achieve a black pixel defining layer. If (e.g., when) forming or providing the pixel defining layer PDL, carbon black may be utilized as a black pigment and/or a black dye, but embodiments of the present disclosure are not limited thereto.

In one or more embodiments, the pixel defining layer PDL may be formed or composed of an inorganic material. For example, the pixel defining layer PDL may be formed or composed of an inorganic material, such as silicon nitride (e.g., SiₓN_{y}, wherein 0<x≤3 and 0<y≤4; e.g., Si₃N₄), silicon oxide (e.g., SiOₓ, wherein 0<x≤2; e.g., SiO₂), and silicon nitride oxide (e.g., SiₓON_{y}, wherein 0<x≤2 and 0<y≤2; e.g., SiON or Si₂ON₂).

A light emitting aperture PX_OP exposing a portion of the first electrode AE may be defined in the pixel defining layer PDL. A portion of the first electrode AE exposed by the light emitting aperture PX_OP may be defined as a light emitting area LA.

The active area AA-DM of the display module DM may include a light emitting area LA and a light shielding area NLA. The area where the pixel defining layer PDL is provided may correspond to the light shielding area NLA. The light shielding area NLA may be around (e.g., surround) the light emitting area LA within the active area AA-DM.

A hole control layer HCL may be provided on the first electrode AE and the pixel defining layer PDL. The hole control layer HCL may be provided as a common layer overlapping the light emitting area LA and the light shielding area NLA. The hole control layer HCL may include at least one of a hole transport layer, a hole injection layer, or an electron blocking layer. The hole control layer HCL may include a hole injection material that is generally available or generally used and/or a hole transport material that is generally available or generally used.

A light emitting layer EML may be provided on the hole control layer HCL. The light emitting layer EML may be provided in an area corresponding to the light emitting aperture PX_OP. In one or more embodiments, the light emitting layer EML may be provided as a common layer. The light emitting layer EML may include an organic light emitting material and/or an inorganic light emitting material. The light emitting layer EML may emit light of any one selected from among red, green, and blue colors. For example, the light emitting layer EML may emit blue light.

An electron control layer TCL may be provided on the light emitting layer EML. The electron control layer TCL may be provided as a common layer overlapping the light emitting area LA and the light shielding area NLA. The electron control layer TCL may include at least one of an electron transport layer, an electron injection layer, or a hole blocking layer. The electron control layer TCL may include an electron injection material that is generally available or generally used and/or an electron transport material that is generally available or generally used.

A second electrode CE may be provided on the electron control layer TCL. The second electrode CE may be provided as a common layer overlapping the light emitting area LA and the light shielding area NLA.

The second electrode CE may be a common electrode. The second electrode CE may be a cathode or an anode. For example, if (e.g., when) the first electrode AE is an anode, the second electrode CE may be a cathode. If (e.g., when) the first electrode AE is a cathode, the second electrode CE may be an anode.

The second electrode (CE) may be a transmissive electrode, a transflective electrode, or a reflective electrode. If (e.g., when) the second electrode CE is a transmissive electrode, the second electrode CE may be formed or composed of a transparent (e.g., substantially transparent) metal oxide, such as indium tin oxide (ITO), indium zinc oxide (IZO), zinc oxide (ZnO), and/or indium tin zinc oxide (ITZO).

If (e.g., when) the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, ytterbium (Yb), W, or a compound or mixture containing thereof (for example, AgMg, AgYb, or MgYb). In one or more embodiments, the second electrode CE may have a multilayer structure including a reflective film and/or a transflective film formed or composed of the material as described herein and a transparent (e.g., substantially transparent) conductive (e.g., electrically conductive) film formed or composed of indium tin oxide (ITO), indium zinc oxide (IZO), zinc oxide (ZnO), indium tin zinc oxide (ITZO), and/or the like. For example, the second electrode CE may include the metal material as described herein, a combination of two or more metal materials selected from among the metal materials as described herein, or an oxide of the metal materials as described herein.

An encapsulation layer TFE may be provided on the second electrode CE to cover the light emitting element ED. The encapsulation layer TFE may include a plurality of thin films. For example, the encapsulation layer TFE may include inorganic films provided on the second electrode CE and an organic film provided between the inorganic films. The inorganic film may protect the light emitting element ED from moisture/oxygen, and the organic film may protect the light emitting element ED from foreign substances, such as dust particles.

The input detection part TP may include a first detection insulating layer IL1, a second detection insulating layer IL2, and a third detection insulating layer IL3. The input detection part TP may include at least one conductive (e.g., electrically conductive) layer provided on the detection insulating layers. The input detection part TP may include a first conductive layer CDL1 and a second conductive layer CDL2.

The first detection insulating layer IL1 may be provided on the encapsulation layer TFE. The first detection insulating layer IL1 may include at least one inorganic insulating (e.g., electrically insulating) layer. The first detection insulating layer IL1 may be in contact with the encapsulation layer TFE. In one or more embodiments, the first detection insulating layer IL1 may not be provided, and in this case, the first conductive layer CDL1 may be in contact with the encapsulation layer TFE.

The first conductive layer CDL1 may be provided on the first detection insulating layer IL1. The first conductive layer CDL1 may include a plurality of first conductive (e.g., electrically conductive) patterns. The plurality of first conductive patterns may be provided on the first detection insulating layer IL1. The second detection insulating layer IL2 may be provided on the first detection insulating layer IL1 to cover at least a portion of the first conductive layer CDL1.

The second conductive layer CDL2 may be provided on the second detection insulating layer IL2. The second conductive layer CDL2 may include a plurality of second conductive (e.g., electrically conductive) patterns. A plurality of second conductive (e.g., electrically conductive) patterns may be provided on a second detection insulating layer IL2. Each of the second conductive patterns may be connected to a plurality of first conductive (e.g., electrically conductive) patterns through a contact hole formed or provided in the second detection insulating layer IL2.

The plurality of the first conductive patterns of the first conductive layer CDL1 and the plurality of the second conductive patterns of the second conductive layer CDL2 may be provided to correspond to a light shielding area NLA. Each of the plurality of the first conductive patterns of the first conductive layer CDL1 and the plurality of the second conductive patterns of the second conductive layer CDL2 may correspond to a mesh pattern.

The third detection insulating layer IL3 may be provided on the second detection insulating layer IL2 and may cover the second conductive layer CDL2. Each of the second detection insulating layer IL2 and the third detection insulating layer IL3 may include an inorganic insulating (e.g., electrically insulating) layer and/or an organic insulating (e.g., electrically insulating) layer.

Each of the first conductive layer CDL1 and the second conductive layer CDL2 may have a single layer structure or a multilayer structure stacked along the third direction DR3. The single layer of the conductive layers CDL1 and CDL2 may include a metal layer and/or a transparent (e.g., substantially transparent) conductive (e.g., electrically conductive) layer. The metal layer may include molybdenum, silver, titanium, copper, aluminum, or an alloy thereof. The transparent conductive layer may include a transparent (e.g., substantially transparent) conductive (e.g., electrically conductive) oxide, such as indium tin oxide (ITO), indium zinc oxide (IZO), zinc oxide (e.g., ZnO), and/or indium zinc tin oxide (IZTO). In one or more embodiments, the transparent conductive layer may include a conductive (e.g., electrically conductive) polymer, such as poly(3,4-ethylenedioxythiophen) (PEDOT), metal nanowires, graphene, and/or the like.

The multilayer of the conductive layers CDL1 and CDL2 may include metal layers. For example, the metal layers may have a three layer structure of titanium (Ti)/aluminum (Al)/titanium (Ti). The multilayer of the conductive layers CDL1 and CDL2 may include at least one metal layer and at least one transparent (e.g., substantially transparent) conductive (e.g., electrically conductive) layer.

FIGS. 7A to 7D are diagrams schematically illustrating a method for manufacturing an adhesive member AP from a resin composition RC according to one or more embodiments. For example, the method for manufacturing an adhesive member AP may include a method of providing a resin composition RC on a substrate CF, a method of providing a first light UV-1 to the resin composition RC to form or provide a preliminary adhesive member P-AP, and a method of providing a second light UV-2 to the preliminary adhesive member P-AP to form or provide the adhesive member AP. Hereinafter, in the description of FIGS. 7A to 7D, any overlapping content with that described with reference to FIGS. 1 to 6 may not be described again, and differences will be primarily described.

Referring to FIG. 7A, the resin composition RC according to one or more embodiments may be provided on a substrate CF. The resin composition RC may be provided on the substrate CF via a nozzle NZ. For example, the substrate CF on which the resin composition RC is provided may include polyethylene terephthalate (PET). The substrate CF is a temporary substrate utilized to form or provide an adhesive member AP (FIGS. 4 and 5) from the resin composition RC, and any suitable material that may be easily detached after the resin composition RC is cured may be utilized without limitation. One surface of the substrate CF on which the resin composition RC is provided may be subjected to a release treatment.

The resin composition RC of one or more embodiments may be provided by an inkjet printing method and/or a dispensing method. In one or more embodiments, the resin composition RC of a liquid phase may be provided in a substantially uniform amount and/or at a substantially uniform rate. FIG. 7A illustrates the resin composition RC being provided through a nozzle NZ, but the device to provide the resin composition RC is not limited thereto.

The resin composition RC of one or more embodiments may include: a monofunctional (meth)acrylate monomer; a urethane (meth)acrylate oligomer; a first compound that does not contain a double bond (e.g., a carbon-carbon double bond, a carbon-nitrogen double bond, a carbon-oxygen double bond, a nitrogen-oxygen double bond, and/or the like) conjugated to a carbonyl group and includes at least one alkene group, where the alkene group is a non-conjugated alkene group; and a photopolymerization initiator (e.g., a photoinitiator). The resin composition RC of one or more embodiments may further include a silane coupling agent. The resin composition RC of one or more embodiments may further include an ultraviolet absorber.

In one or more embodiments, (meth)acryl refers to acryl or methacryl, and (meth)acrylate refers to acrylate or methacrylate.

In the resin composition RC of one or more embodiments, the monofunctional (meth)acrylate monomer may include at least one of 4-hydroxybutyl acrylate, tetrahydrofurfuryl acrylate, dodecyl acrylate, 2-methoxyethyl acrylate, ethyl acrylate, isobornyl acrylate, or isodecyl acrylate. The monofunctional (meth)acrylate monomer may be of one type or kind, or two or more types or kinds may be utilized in combination.

The content (e.g., amount) of the monofunctional (meth)acrylate monomer may be, for example, in the range of about 67 wt % to about 95 wt % based on a total of 100 wt % of the resin composition. However, this is an example, and the content (e.g., amount) of the monofunctional (meth)acrylate monomer may be suitably adjusted, depending on the content (e.g., amount) of the urethane (meth)acrylate oligomer and the first compound, as long as the scope and features of the present disclosure do not change.

In the resin composition RC of one or more embodiments, the content (e.g., amount) of the urethane (meth)acrylate oligomer may be in the range of about 1 wt % to about 30 wt %, based on a total of 100 wt % of the resin composition. If (e.g., when) the content (e.g., amount) of the urethane (meth)acrylate oligomer exceeds the foregoing range, the viscosity of the resin composition may increase excessively or substantially, and discharging properties may be poor. In one or more embodiments, if (e.g., when) the content (e.g., amount) of the urethane (meth)acrylate oligomer is less than the foregoing range, the polymerization reaction may not sufficiently or suitably occur during curing, and curing properties may be poor.

In the resin composition RC of one or more embodiments, the urethane (meth)acrylate oligomer may be one type or kind, or two or more types or kinds may be utilized in combination.

In the resin composition RC of one or more embodiments, the urethane (meth)acrylate oligomer may have a weight average molecular weight (M_{w}) in the range of about 3,000 g/mol to about 50,000 g/mol. The weight average molecular weight may be a value derived using gel permeation chromatography and converted by standard polystyrene.

In the resin composition of one or more embodiments, the first compound may not include a double bond (e.g., a carbon-carbon double bond, a carbon-nitrogen double bond, a carbon-oxygen double bond, a nitrogen-oxygen double bond, and/or the like) conjugated with a carbonyl group and may include at least one alkene group. The alkene group included in the first compound may be a non-conjugated alkene group. Herein, conjugation may refer to a structure in which double bonds and single bonds (or unshared electron pairs) are alternately arranged, causing the p orbitals of adjacent atoms to overlap, thereby widely dispersing electrons throughout the molecule.

In the first compound, not including a double bond conjugated with a carbonyl group may refer to a structure in which the carbon-oxygen double bond of the carbonyl group and another double bond are arranged with a single bond between them, is not included. Furthermore, not including a double bond conjugated with a carbonyl group may also include cases where the carbonyl group itself is not present.

In this case, the double bond may include both a double bond between homologous elements and a double bond between heterologous elements. For example, a double bond between homologous elements may include a carbon-carbon double bond. For example, a double bond between heterologous elements may include a carbon-nitrogen double bond, a carbon-oxygen double bond, a nitrogen-oxygen double bond, and/or the like.

A functional group having a double bond conjugated with a carbonyl group may include, for example, a (meth)acrylate group, a (meth)acryloyl group, and/or the like. The first compound may refer to a compound that does not include, for example, a (meth)acrylate group.

The first compound may include at least one alkene group. The alkene group included in the first compound may be a non-conjugated alkene group. For example, all alkene groups included in the first compound may be non-conjugated alkene groups. The first compound may not include a conjugated alkene group.

In the first compound, the non-conjugated alkene group may refer to a carbon-carbon double bond that is not conjugated to another double bond. The non-conjugated alkene group may refer to a carbon-carbon double bond that is not connected to another double bond or an electron-donating group via a single bond.

For example, if (e.g., when) only one alkene group exists in the whole compound, the group may be a non-conjugated alkene group. In one or more embodiments, even if (e.g., when) two or more alkene groups are contained in a compound, if (e.g., when) the alkene groups are not connected via a single bond, the groups may be non-conjugated alkene groups.

The weight average molecular weight (M_{w}) of the first compound may be in the range of about 28 g/mol to about 2,500 g/mol. For example, the weight average molecular weight (M_{w}) of the first compound may be in the range of about 28 g/mol to about 2,000 g/mol, about 28 g/mol to about 1,500 g/mol, about 28 g/mol to about 1,000 g/mol, or about 28 g/mol to about 800 g/mol. In this case, the weight average molecular weight may be measured using gel permeation chromatography, but is not limited thereto as long as a method that may be suitably selected by a person skilled in the art. If (e.g., when) the weight average molecular weight of the first compound exceeds about 2,500 g/mol, the adhesion and light resistance after curing may be poor. This may be because the high molecular weight leads to poor miscibility with (meth)acrylate monomers and urethane (meth)acrylate oligomers. Among the compounds that may satisfy the definition of the first compound, the compound having the lowest molecular weight may be ethylene. Because the molecular weight of ethylene is 28 g/mol, the weight average molecular weight (M_{w}) of the first compound may be about 28 g/mol or more.

For example, in the resin composition RC of one or more embodiments, the first compound may include at least one selected from among pinene derivatives, rosin derivatives, polybutadiene, limonene, cholesterol derivatives, and diprenyl glycerin ether.

The pinene derivative may include at least one selected from among (1S)-(−)-α-pinene and α-terpineol.

The rosin derivative may include dihydroabietic acid.

In the resin composition RC of one or more embodiments, the content (e.g., amount) of the first compound may be in the range of about 0.1 wt % to about 15 wt % based on a total of 100 wt % of the resin composition. If (e.g., when) the content (e.g., amount) of the first compound is less than about 0.1 wt %, light resistance after curing may be poor. If (e.g., when) the content (e.g., amount) of the first compound exceeds about 15 wt %, curability may be poor, and the manufacture of an adhesive member and/or the like may be difficult.

The resin composition RC of one or more embodiments may exhibit excellent or suitable light resistance and adhesive strength after curing by including the first compound. The first compound in the resin composition may be one type or kind, or two or more types or kinds in combination.

The resin composition RC of one or more embodiments may include a photopolymerization initiator (e.g., a photoinitiator). The photopolymerization initiator may refer to a material that absorbs light, such as ultraviolet rays, and may induce a polymerization reaction of a monomer and/or an oligomer.

For example, the photopolymerization initiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In one or more embodiments, the photopolymerization initiator may include at least one of 2-methyl-1-[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl)phosphine oxide, [1-(4-phenylsulfanylbenzoyl)heptylideneamino]benzoate, [1-[9-ethyl-6-(2-methylbenzoyl) carbazol-3-yl]ethylideneamino]acetate, or bis(2,4-cyclopentadienyl)bis [2,6-difluoro-3-(1-pyryl)phenyl]titanium (IV).

In one or more embodiments, the resin composition RC may include a cleavage-type or kind photopolymerization initiator as a photopolymerization initiator (e.g., a photoinitiator). A cleavage-type or kind photopolymerization initiator refers to a type or kind of photopolymerization initiator that initiates polymerization by generating radicals or cations if (e.g., when) bonds are cleaved by light. Examples of the cleavage-type or kind photopolymerization initiator include any suitable compound, for example, bis(2,4,6-trimethylbenzoyl)phenyl phosphine oxide, without limitation, as long as the compound is generally available to or generally used by those skilled in the art as a cleavage-type or kind photopolymerization initiator.

In one or more embodiments, the resin composition RC may include bis(2,4,6-trimethylbenzoyl)phenyl phosphine oxide as the photopolymerization initiator.

The photopolymerization initiator may be a single type or kind, or two or more types or kinds may be utilized in combination. However, the photopolymerization initiator is not limited to the types or kinds described herein, and any type or kind of photopolymerization initiator capable of being suitably selected by those skilled in the art may be utilized without limitation.

The resin composition RC of one or more embodiments may further include a silane coupling agent. Silane coupling agents, such as KBM-5103 from Shin-Etsu Chemical, Inc., may be utilized, but are not limited thereto as long as they are suitably selected by those skilled in the art. The silane coupling agent in the resin composition may be present in an amount less than about 1 wt % based on a total of 100 wt % of the resin composition.

The resin composition RC of one or more embodiments may further include a UV absorber, such as Tinuvin 329 from BASF.

The resin composition RC of one or more embodiments may have a yellowness index in the range of about 0.1 to about 1.5, measured immediately after photocuring, under conditions where the integrated light quantity (integrated light dose) in the atmosphere at wavelengths of about 365 nm and about 395 nm is in the range of about 1600 mJ/cm² to about 2000 mJ/cm². If (e.g., when) a yellowness index exceeds about 1.5 measured immediately after photocuring, it may indicate discoloration of the adhesive member due to curing.

The resin composition RC of one or more embodiments may have a yellowness index in the range of about 0.1 to about 1.5 after exposure to light for about 120 hours under the conditions of about 0.4 W/m² at about 340 nm and about 50 °C after the photocuring as described herein. This may indicate that the yellowness index is in the range of about 0.1 to about 1.5 after a light resistance test for about 120 hours. If (e.g., when) a yellowness index exceeds about 1.5 after the light resistance test, it may indicate that the adhesive member has low resistance to discoloration, fading, and/or the like if (e.g., when) exposed to sunlight and/or the like.

The resin composition RC of one or more embodiments may have a difference value in the range of about-1.0 to about 1.0 between a yellowness index measured immediately after photocuring under the conditions of an integrated light dose in the range of about 1600 mJ/cm² to about 2000 mJ/cm² at wavelengths of about 365 nm and about 395 nm in the air, and a yellowness index after photocuring and after exposure for about 120 hours under the conditions of about 0.4 W/m² at about 340 nm and about 50 °C. The difference between a yellowness index immediately after photocuring and a yellowness index after light resistance test for about 120 hours in the range of about-1.0 to about 1.0 may indicate that the resin composition exhibits little color change even if (e.g., when) exposed to light for a long period of time after curing.

The yellowness index in the present disclosure may refer to a value measured using a spectral colorimeter/haze meter (COH 7700, Nippon Denshoku).

After photocuring the resin composition RC of one or more embodiments by exposing to LED light at an integrated light dose of about 1,800 mJ/cm² in the air, a 180° peel strength on a glass substrate measured at about 25 °C may be in the range of about 1,500 gf/25 mm to about 6,000 gf/25 mm. After curing, a resin composition RC having a 180° peel strength of less than about 1500 gf/25 mm at room temperature with respect to a glass substrate may not have sufficient or suitable bonding strength to an adjacent display device component (for example, a display module and/or a window).

The resin composition RC of one or more embodiments may have a shear viscosity in the range of about 8 mPa·s to about 50 mPa·s, as measured by a JIS Z 8803 method at about 30 °C. If (e.g., when) the shear viscosity exceeds about 50 mPa·s, the composition may not be easily discharged from an inkjet printing device or a dispensing device if (e.g., when) applied to a substrate, resulting in reduced processability. If (e.g., when) the shear viscosity is less than about 8 mPa·s, the discharged amount may not be easily or suitably controlled. In one or more embodiments, if (e.g., when) the viscosity of the resin composition satisfies the foregoing range, the composition may exhibit excellent or suitable coating properties and adhesive strength after curing.

The resin composition RC of one or more embodiments may have a three-point bending strength (3PB) measured at about 30 °C after curing in the range of about 35 N to about 60 N. If (e.g., when) the three-point bending strength is less than about 35 N, mechanical durability may be poor. In one or more embodiments, if (e.g., when) the three-point bending strength exceeds about 60 N, the cured resin composition may be highly or substantially brittle. In one or more embodiments, if (e.g., when) the three-point bending strength satisfies the foregoing range, adhesive strength and durability may be adequately or suitably secured.

Accordingly, the resin composition RC of one or more embodiments may have low viscosity before curing and exhibit excellent or suitable adhesive reliability and excellent or suitable display quality after curing. In one or more embodiments, an adhesive member formed or provided by curing the resin composition RC according to one or more embodiments and an electronic apparatus including the adhesive member may also have excellent or suitable adhesive reliability.

Referring to FIG. 7B, a first light UV-1 may be provided to a resin composition RC applied to a substrate CF having a substantially constant thickness. The resin composition RC having a liquid phase may be cured by the first light UV-1 to form or provide a preliminary adhesive member P-AP (FIG. 7C). The first light UV-1 may be ultraviolet rays. In FIG. 7B, the first light UV-1 is directly irradiated to the resin composition RC applied to the substrate CF to form or provide the preliminary adhesive member P-AP, but embodiments of the present disclosure are not limited thereto. A carrier film may be provided on the resin composition RC applied to a substantially uniform thickness, and the carrier film may be capable of transmitting ultraviolet rays.

Referring to FIGS. 7C and 7D, the preliminary adhesive member P-AP formed or provided by irradiating the resin composition RC with the first light UV-1 (FIG. 7B) may be detached from the substrate CF and provided on one side of a window WP or one side of a display module DM. One side of the preliminary adhesive member P-AP may be stacked on one side of the window WP or one side of the display module DM, and one side of the display module DM or one side of the window WP that is not attached may be attached to the remaining side of the preliminary adhesive member P-AP. Then, a second light UV-2 may be irradiated to the preliminary adhesive member P-AP to form or provide an adhesive member AP (FIGS. 4 and 5). The second light UV-2 may be ultraviolet rays. The second light UV-2 may be provided from the upper portion of the window WP, and the window WP may transmit the second light UV-2. The second light UV-2 may be transmitted through the window WP and applied to the preliminary adhesive member P-AP. In one or more embodiments, the second light UV-2 may be transmitted through a printed layer BM and applied to the preliminary adhesive member P-AP.

A region of the preliminary adhesive member P-AP overlapping the printed layer BM may be irradiated with a smaller amount of the second light UV-2 than another region of the preliminary adhesive member P-AP not overlapping the printed layer BM.

FIGS. 7A to 7D illustrate that the resin composition RC is cured twice (for example, cured by applying light twice) to form or provide the adhesive member AP (FIGS. 4 and 5), but embodiments of the present disclosure are not limited thereto. For example, the adhesive member AP may be formed or provided by curing the resin composition RC once or three or more times.

FIGS. 8A to 8C are diagrams schematically illustrating another method for manufacturing an adhesive member AP from the resin composition RC according to one or more embodiments. Hereinafter, in the description of FIGS. 8A to 8C, any overlap with the description with reference to FIGS. 1 to 7D may not be described again, and differences will be primarily discussed.

The method for manufacturing the adhesive member AP illustrated in FIGS. 8A to 8C may include a method of providing a resin composition RC on a display module DM, a method of providing a first light UV-1 to the resin composition RC to form or provide a preliminary adhesive member P-AP, and a method of providing a second light UV-2 to the preliminary adhesive member P-AP to form or provide the adhesive member AP. The manufacturing method illustrated in FIGS. 8A to 8C differs from the manufacturing method illustrated in FIGS. 7A to 7D in that the resin composition RC is provided on the display module DM.

The resin composition RC may be directly provided to one side of the display module DM or one side of the window WP. In FIG. 8A, the resin composition RC is illustrated as being provided directly to one side of the display module DM.

Referring to FIG. 8B, a first light UV-1 may be applied to the substantially uniformly applied resin composition RC. As the first light UV-1 is applied to the resin composition RC, a preliminary adhesive member P-AP may be formed or provided. A window WP may be provided on the preliminary adhesive member P-AP. Referring to FIG. 8C, a second light UV-2 may be transmitted through the window WP and provided to the preliminary adhesive member P-AP. In one or more embodiments, the second light UV-2 may be transmitted through a printed layer BM and applied to the preliminary adhesive member P-AP. The preliminary adhesive member P-AP may be cured by the second light UV-2 to form or provide an adhesive member AP (FIG. 5).

The adhesive member AP (FIG. 5) formed or made from the resin composition RC of one or more embodiments may exhibit high adhesive strength. Furthermore, the adhesive member AP (FIG. 5) formed or made from the resin composition RC of one or more embodiments may exhibit high adhesive strength even under the printed layer BM.

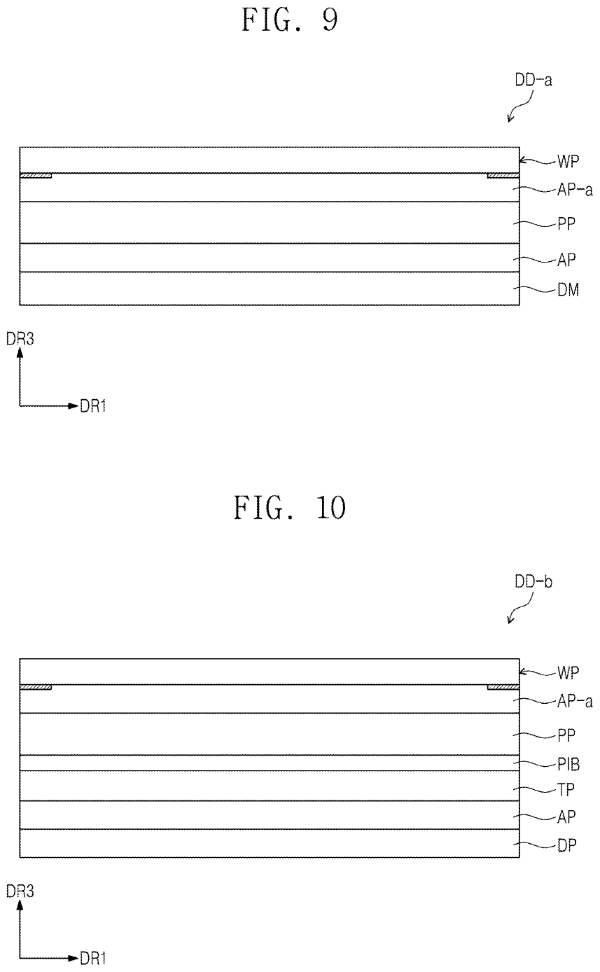

FIGS. 9 and 10 are cross-sectional views illustrating display devices according to one or more embodiments. Hereinafter, in the description of the display devices according to one or more embodiments described with reference to FIGS. 9 and 10, any overlapping information with that described with reference to FIGS. 1 to 8C may not be described again, and differences will be primarily described.

Compared to the display device DD described with reference to FIGS. 4 and 5, a display device DD-a illustrated in FIG. 9 may further include a light control layer PP and an optical adhesive layer AP-a. The display device DD-a according to one or more embodiments may further include a light control layer PP provided between an adhesive member AP and a window WP, and an optical adhesive layer AP-a provided between the light control layer PP and the window WP. The light control layer PP may include a polarizing plate, or the light control layer PP may include a color filter layer.

The optical adhesive layer AP-a may be formed or made from the resin composition RC according to one or more embodiments. The optical adhesive layer AP-a including a polymer derived from the resin composition RC may exhibit excellent or suitable adhesive strength. The display device DD-a including the optical adhesive layer AP-a may exhibit excellent or suitable reliability and excellent or suitable display quality.

Compared to the display device DD described with reference to FIGS. 4 and 5, a display device DD-b according to one or more embodiments illustrated in FIG. 10 may further include a light control layer PP, an optical adhesive layer AP-a, and an interlayer adhesive layer PIB.

In the display device DD-b of one or more embodiments, an adhesive member AP may be provided between a display panel DP and an input detection part TP. For example, the input detection part TP may not be directly on the display panel DP, but rather the display panel DP and the input detection part TP may be bonded to each other by the adhesive member AP. For example, the adhesive member AP may be provided between the encapsulation layer TFE (FIG. 5) of the display panel DP and the input detection part TP.

An interlayer adhesive layer PIB may be provided at the lower side of the light control layer PP. The interlayer adhesive layer PIB may be provided between the input detection part TP and the light control layer PP and may be formed or composed of an adhesive material having excellent or suitable moisture permeability prevention. For example, the interlayer adhesive layer PIB may be formed or provided by including polyisobutylene. The interlayer adhesive layer PIB may be provided on the input detection part TP to prevent corrosion (or to reduce a degree or occurrence of corrosion) of the detection electrodes of the input detection part TP. The display device DD-b according to one or more embodiments may include the optical adhesive layer AP-a and the adhesive member AP formed or made from the resin composition RC according to one or more embodiments, and the display device DD-b including the optical adhesive layer AP-a and the adhesive member AP may exhibit excellent or suitable reliability and excellent or suitable display quality.

Hereinafter, a resin composition according to one or more embodiments of the present disclosure and an adhesive member formed or made from the resin composition will be described in more detail with reference to examples and comparative examples. Also, the examples shown below are examples to help understanding of the present disclosure, and the scope of the present disclosure is not limited thereto.

### EXAMPLES

Table 1 shows the components and contents (e.g., amounts) of the resin compositions of the Examples, and Table 2 shows the components and contents (e.g., amounts) of the resin compositions of the Comparative Examples. The components of Tables 1 and 2 were mixed into a resin composition having a liquid phase by stirring the mixture using a roll mill at room temperature for about 12 hours.

The resin compositions of Examples 1 to 10 include a monofunctional (meth)acrylate monomer, a urethane (meth)acrylate oligomer, a photopolymerization initiator (e.g., a photoinitiator), and a first compound. Also, the resin compositions of Examples 1 to 10 further include a silane coupling agent. The resin compositions of Examples 7 to 10 further include an ultraviolet absorber.

The Examples include 4-HBA, IBXA, THF-A, and IDAA as the monofunctional (meth)acrylate monomers, and at least one selected from among UA-1, UA-2, and UA-3 as the urethane (meth)acrylate oligomers. The content (e.g., amount) of the monofunctional (meth)acrylate monomer is in the range of about 67 wt % to about 95 wt % based on a total of 100 wt % of the resin composition, and the content (e.g., amount) of the urethane (meth)acrylate oligomer is in the range of about 1 wt % to about 30 wt % based on a total of 100 wt % of the resin composition. The Examples include Omnirad 819 as the photopolymerization initiator and KBM-5103 as the silane coupling agent. The resin compositions of Examples 7 to 9 include Tinuvin 329 as the ultraviolet absorber.

The first compound of the Examples does not contain a double bond conjugated with a carbonyl group and includes a non-conjugated alkene group. The first compound of the Examples does not contain a conjugated alkene group. The weight average molecular weight of the first compound is in the range of about 28 g/mol to about 2,500 g/mol, and the content (e.g., amount) of the first compound is in the range of about 0.1 wt % to about 15 wt % based on a total of 100 wt % of the resin composition.

The resin compositions of Comparative Examples 1, 2, 5, and 6 differ from the Examples in including compounds that do not conform to the first compound.

For example, the compound used in the resin composition of Comparative Example 1 does not contain a non-conjugated alkene group. The compound used in the resin composition of Comparative Example 2 does not contain an alkene group. The compound used in the resin composition of Comparative Example 5 has a weight average molecular weight of greater than about 2,500 g/mol. The compound used in the resin composition of Comparative Example 6 contains a double bond conjugated to a carbonyl group.

The resin composition of Comparative Example 3 differs from the Examples in that the content (e.g., amount) of the first compound exceeds about 15 wt % based on a total of 100 wt % of the resin composition.

The resin composition of Comparative Example 4 differs from the Examples in that the first compound is not contained.

The resin composition of Comparative Example 7 differs from the Examples in that the content (e.g., amount) of the urethane (meth)acrylate oligomer exceeds about 30 wt % based on a total of 100 wt % of the resin composition.

The resin compositions of Examples 1 and 3 differ in the type or kind of the first compound, but the remaining components and contents (e.g., amounts) are identical.

The resin compositions of Examples 2 and 4 differ in the type or kind of the first compound, but the remaining components and contents (e.g., amounts) are identical.

The resin compositions of Examples 5 and 6 differ in the content (e.g., amount) of the first compound and the content (e.g., amount) of the monofunctional (meth)acrylate monomer.

The resin composition of Example 7 differs from the resin composition of Example 6 in that an ultraviolet absorber is added.

The resin compositions of Examples 8 and 9 use different first compounds than the other Examples, and each uses a different type or kind of urethane (meth)acrylate oligomer.

The resin composition of Example 10 differs from the other Examples in the content (e.g., amount) of the urethane (meth)acrylate oligomer.

The urethane (meth)acrylate oligomers UA-1 to UA-3 used in Tables 1 and 2 are as follows:

### UA-1

UV-3300B product of Mitsubishi Chemical Co. was used. The weight average molecular weight (M_{w}) was 13,000 g/mol.

### UA-2

To a four-necked flask equipped with a condenser, a dry air inlet, a temperature sensor, and a stirrer, 469 g of BA-P8, 92.8 g of PLACCEL FA1DDM, 104 g of 2,2-bis(hydroxymethyl) butyric acid, 2.11 g of BHT, 0.211 g of MEHQ, 0.050 g of DBTDDL, and 485 g of THF-A were added and mixed at about 70 °C. After confirming that the raw materials were melted, the mixture was cooled to about 60 °C in air, and 388 g of 1,3-bis(isocyanatomethyl)cyclohexane was added dropwise in four portions to prepare a mixture. While maintaining the temperature of the mixture at about 75 °C, the reaction was conducted. After confirming that the isocyanate content (e.g., amount) was about 3.0 wt % or less based on a total of 100 wt % of the mixture, 37.2 g of ethanol was added and stirred for about 1.5 hours. After confirming that the isocyanate content (e.g., amount) (NCO %) was about 0.1 wt % or less based on a total of 100 wt % of the mixture including ethanol, the mixture was cooled in air to obtain 1 urethane acrylate UA-2. In this case, the weight average molecular weight (M_{w}) of UA-2 was 7,000 g/mol.

The method for measuring the isocyanate content (e.g., amount) (NCO %) in the preparation method as described herein follows JIS K6806. For example, about 4.000 g to about 5.000 g of a sample was weighed into a conical beaker, 15 mL of ethyl acetate was added, and the sample was stirred for about 15 minutes using a stirrer to dissolve the sample. After that, 10 mL of an ethyl acetate solution having 0.75 mol/L of dibutylamine was added to the beaker and stirred at about 50 °C for about 10 minutes. After stirring, 20-30 drops of a colorimetric reagent (0.1 wt % promophenol blue in ethanol (50) solution) were added to the beaker and titrated with 0.5 mol/L methanolic hydrochloric acid. The endpoint was determined at the point where the solution turned yellow (equivalent to pH=2).

### UA-3

To a four-necked flask equipped with a condenser, a dry air inlet tube, a temperature sensor, and a stirrer, 535 g of BA-P8, 61.7 g of PLACCEL FA1DDM, 119 g of 2,2-bis(hydroxymethyl) butyric acid, 2.20 g of BHT, 0.221 g of MEHQ, 0.050 g of DBTDDL, and 485 g of THF-A were added and mixed at about 70 °C. After confirming that the raw materials were melted, the mixture was cooled to about 60 °C in air, and 388 g of 1,3-bis(isocyanatomethyl)cyclohexane was added dropwise in four portions to prepare a mixture. While maintaining the temperature of the mixture at about 75 °C, the reaction was continued until the isocyanate content (e.g., amount) (NCO %) was about 1.2 wt % or less based on a total of 100 wt % of the mixture. Then, 24.7 g of ethanol was added and stirred for about 1.5 hours. After confirming that the isocyanate content (e.g., amount) (NCO %) was about 0.1 wt % or less based on a total of 100 wt % of the mixture including ethanol, the mixture was cooled in air to obtain 1 urethane acrylate UA-3. The weight average molecular weight (M_{w}) of UA-3 was 13,000 g/mol.

The raw materials used in the synthesis of UA-2 and UA-3 are as follows.

BA-P8: 2,2-Bis [4-polyoxypropylene oxyphenyl]propane-based glycol (product of Nippon Nyukazai)

PLACCEL FA1DDM: Caprolactone modified acrylate (product of Daicel Co., Ltd.)

BHT: Dibutyl hydroxytoluene

MEHQ: 4-Methoxyphenol

DBTDDL: Dibutyltin Dilaurate

THF-A: Tetrahydrofurfuryl acrylate (product of Kyoeisha Chemical)

TABLE 1

| | | Example | Example | Example | Example | Example | Example | Example | Example | Example | Example |
|---|---|---|---|---|---|---|---|---|---|---|---|
| | | 1 | 2 | 3 | 4 | 5 | 6 | 7 | 8 | 9 | 10 |
| Monofunctional | 4-HBA | 13.0 | 12.5 | 13.0 | 12.5 | 13.1 | 13.1 | 13.0 | 13.2 | 13.1 | 10.3 |
| (meth)acrylate | IBXA | 17.4 | 16.7 | 17.4 | 16.7 | 17.5 | 17.4 | 17.4 | 17.5 | 17.5 | 22.4 |
| monomer | THF-A | 39.0 | 37.5 | 39.0 | 37.5 | 39.3 | 39.1 | 39.0 | 39.4 | 39.3 | 37.2 |
| | IDAA | 13.0 | 12.5 | 13.0 | 12.5 | 13.1 | 13.1 | 13.0 | 13.2 | 13.1 | 21.5 |
| Monofunctional (meth)acrylate | | 82.4 | 79.2 | 82.4 | 79.2 | 83.0 | 82.7 | 82.4 | 83.3 | 83.0 | 91.4 |
| monomer total amount (wt %) | | | | | | | | | | | |
| Urethane | UA-1 | | | | | | | | | | 2.1 |
| (meth)acrylate | UA-2 | 14.8 | 14.2 | 14.8 | 14.2 | 14.9 | 14.8 | 14.8 | | 14.9 | |
| oligomer | UA-3 | | | | | | | | 14.9 | | |
| Silane coupling | KBM-5103 | 0.4 | 0.4 | 0.4 | 0.4 | 0.4 | 0.4 | 0.4 | 0.4 | 0.4 | 0.5 |
| agent | | | | | | | | | | | |
| Photopoly- | Omnirad 819 | 1.5 | 1.4 | 1.5 | 1.4 | 1.2 | 1.2 | 1.2 | 1.2 | 1.5 | 1.4 |
| merization | | | | | | | | | | | |
| initiator | | | | | | | | | | | |
| First | Dihydroabietic | 1.0 | | | | | | | | | |
| compound | acid | | | | | | | | | | |
| | α-Terpineol | | 4.7 | | | | | | | | |
| | (1S)-(-)-α- | | | 1.0 | 4.7 | 0.5 | 1.0 | 1.0 | | | 4.7 |
| | Pinene | | | | | | | | | | |
| | DPNG | | | | | | | | 0.1 | 0.1 | |
| Ultraviolet | Tinuvin 329 | | | | | | | 0.1 | 0.1 | 0.1 | |
| absorber | | | | | | | | | | | |

TABLE 2

| | | Com- | Com- | Com- | Com- | Com- | Com- | Com- |
|---|---|---|---|---|---|---|---|---|
| | | parative | parative | parative | parative | parative | parative | parative |
| | | Example | Example | Example | Example | Example | Example | Example |
| | | 1 | 2 | 3 | 4 | 5 | 6 | 7 |
| Monofunctional | 4-HBA | 12.6 | 10.5 | 10.6 | 13.1 | 9.8 | 12.6 | 6.2 |
| (meth)acrylate | IBXA | 16.7 | 14.0 | 14.1 | 17.5 | 20.5 | 12.6 | 6.2 |
| monomer | THF-A | 37.6 | 31.4 | 31.6 | 39.4 | 35.5 | 16.8 | 18.5 |
| | IDAA | 12.6 | 10.5 | 10.6 | 13.1 | 21.4 | 25.2 | 8.2 |
| Monofunctional | | 79.5 | 66.4 | 66.9 | 83.1 | 87.2 | 67.2 | 39.1 |
| (meth)acrylate monomer total | | | | | | | | |
| amount (wt %) | | | | | | | | |
| Urethane | UA-1 | | | | | 2.0 | | 60.0 |
| (meth)acrylate | UA-2 | 14.2 | 11.9 | 12.0 | 14.9 | | 14.3 | |
| oligomer | UA-3 | | | | | | | |
| Silane coupling | KBM-5103 | 0.4 | 0.3 | 0.4 | 0.4 | 0.4 | 0.4 | 0.2 |
| agent | | | | | | | | |
| Photopolymerization | Omnirad | 1.2 | 1.8 | 1.0 | 1.5 | 1.3 | 1.3 | 0.6 |
| initiator | 819 | | | | | | | |
| First compound | Dihydroabie | | | | | | | |
| | tic acid | | | | | | | |
| | α-Terpineol | | | | | | | |
| | (1S)-(-)-α- | | | 19.8 | | | | |
| | Pinene | | | | | | | |
| | DPNG | | | | | | | 0.1 |
| Compound that | Polyvest110 | | | | | 9.0 | | |
| do not match the | Abietic acid | 4.7 | | | | | | |
| first compound | PE-590 | | 19.6 | | | | | |
| | FA-512AS | | | | | | 16.8 | |
| Ultraviolet | Tinuvin 329 | | | | | | | 0.1 |
| absorber | | | | | | | | |

The compounds used in Tables 1 and 2 are as follows. The contents (e.g., amounts) in Tables 1 and 2 are calculated based on a total of 100 wt % of the resin composition, expressed in weight percent, and rounded to the second decimal place. In this case, the weight of each component was measured using a light shielding glass vial.

Also, molecular weight was measured using a gel permeation chromatography (GPC) analyzer, “HLC-8420GPC” of TOSOH Co. A TSKgel SUPER HZM-N column was used, and tetrahydrofuran (THF) was used as a measuring solvent (e.g., an eluent). A weight average molecular weight calculated by converting to standard polystyrene (PS) from a size exclusion chromatography (SEC) curve detected by a refractive index (RI) detector was applied.

### Monofunctional (Meth)acrylate Monomer

4-HBA: 4-Hydroxybutyl acrylate (product of Osaka Organic Chemical Industry Co., Ltd.)

IBXA: Isobornyl acrylate (product of Osaka Organic Chemical Industry Co., Ltd.)

THF-A: Tetrahydrofurfuryl acrylate (product of Kyoeisha Chemical Co., Ltd.)

IDAA: Isodecyl acrylate (product of Osaka Organic Chemical Industry Co., Ltd.)

### Silane Coupling Agent

KBM-5103:3-(Trimethoxysilyl) propyl acrylate (product of Shin-Etsu Chemical Co., Ltd.)

### Photopolymerization Initiator

Omnirad819: Bis(2,4,6-trimethylbenzoyl)phenyl phosphine oxide (product of IGM Resin)

### First Compound

Dihydroabietic acid: Dihydroabietic acid (molecular weight: 302 g/mol, product of Tokyo Chemical Industry)

α-Terpineneol: α-Terpineneol (molecular weight: 154 g/mol, product of Tokyo Chemical Industry)

(1S)-(−)-α-Pinene: (1S)-(−)-α-Pinene (molecular weight: 136 g/mol, product of Tokyo Chemical Industry)

DPNG: Diprenyl glyceryl ether (molecular weight: 228 g/mol, product of Kuraray)

Compounds that do not Match the First Compound

FA-512AS: Dicyclopentenyloxyethyl acrylate (product of Resonac)

Polyvest110: Liquid polybutadiene (molecular weight: 2,600 g/mol, product of Evonik)

Abietic acid: Abietic acid (molecular weight: 302 g/mol, product of Tokyo Chemical Industry)

PE-590: Hydrogenated rosin (product of Arakawa Chemical Industry, softening point: about 92 °C)

### Ultraviolet Absorber

Tinuvin 329:2-Phenol, 2-(2H-benzotriazol-2-yl)-4-(1,1,3,3-tetramethylbutyl) (product of BASF)

Hereinafter, Tables 3 and 4 show the properties of the resin composition and the physical properties of the adhesive formed or provided by curing the resin composition. The evaluation methods for each property are as follows.

### Shear Viscosity Measurement

The resin compositions of a liquid phase of the Examples and Comparative Examples were measured at about 30 °C and about 10 rpm using a viscometer (TVE-25L, Toki Sangyo Co., Ltd.) in accordance with JIS Z 8803.

### Curability Evaluation

The resin compositions of the Examples and Comparative Examples were applied to a 26 mm×76 mm soda lime glass (Central Glass Co., Ltd.) using an inkjet printer of Microjet Co. to a thickness of about 100 μm, and the cured samples were prepared by irradiating with LED light. The LED light was irradiated to a total integrated light dose of about 1,800 mJ/cm². Curability was evaluated when the resin composition was pressed and then removed with a finger. The evaluation criteria are as follows. In this case, poor curability refers to the formation of fibrils upon removal of the finger.
◯: Excellent curability

x: Poor curability

-: Not discharged, and sample production was impossible

### Three-Point Bending Strength (3PB) Measurement

10 μL of each resin composition of the Examples or Comparative Examples was dropped onto a 26 mm×76 mm soda-lime glass (Central Glass Co., Ltd.), centered at the intersection of 17 mm from the short side and 17 mm from the long side, to form or provide a 6 mm diameter and a 200 μm thickness. The soda-lime glass coated with the resin composition was irradiated with an LED lamp having peak wavelengths of about 365 nm and about 395 nm to an integrated light dose of about 1,800 mJ/cm². Then, a separately prepared 26 mm×76 mm soda-lime glass was then placed on the top of the resin composition, 25 mm from the short side. After overlapping, the size was 26 mm×127 mm, and two slide glasses were bonded using the 6 mm diameter composition. Test specimen was double-clipped for about 12 hours to produce a specimen used for measuring 3PB strength.

After removing the clips from the specimen, the 3PB strength was measured using a three-point bending tester at about 30 °C, applying a load at a rate of about 10 mm/min. The 3PB strength was determined as the maximum value measured until peeling.

### Measurement of Peel Strength

The resin compositions listed in Table 1 were applied to a 26 mm×76 mm soda lime glass (Central Glass Co., Ltd.) using an inkjet printer of Microjet Co. to a thickness of about 100 μm, and the cured samples were prepared by irradiating with LED light. The LED light was irradiated to an integrated light dose of about 1,800 mJ/cm². A specimen was obtained by bonding a 20 mm×150 mm PET film (A4360, 50 μm, Toyobo Co., Ltd.) to the UV-irradiated soda lime glass at a bonding pressure of about 0.15 MPa.

The prepared specimen was tested for peel strength using a universal material testing machine (Instron Co., Ltd., Model 5965 type or kind) at about 25 °C and a peel angle of about 180° at a speed of about 300 mm/min. The peel strength was evaluated by multiplying the average value obtained by peeling about 50 mm by 1.25.

### Yellowness Index (YI) Measurement of Adhesive Member

The resin compositions of the Examples or Comparative Examples were dropped onto a slide glass (Matsunami Glass Slide Glass S1112) equipped with a 200 μm-thick silicone spacer, and then another slide glass was placed thereon. After that, ultraviolet rays were irradiated using an LED lamp having peak wavelengths of about 365 nm and about 395 nm to an integrated light dose of about 1,800 mJ/cm², to obtain a cured specimen of the resin composition.

The yellowness index of the obtained immediately after curing was measured. The yellowness index (YI) was measured using a spectrophotometer⋅haze meter (COH 7700) of Nippon Denshoku Co., Ltd.

The cured specimen, for which the initial yellowness index was measured, was subjected to a light resistance test for about 120 hours. For example, a weather tester (Q-LAB) equipped with a xenon arc lamp was used to irradiate the specimen at wavelengths ranging from about 280 nm to about 3,000 nm, at a light intensity of about 0.4 W/m² at about 340 nm, and at about 50 °C for about 120 hours. Then, the yellowness index of the specimen was then measured again.

The initial yellowness index (YI_{0 hr}) immediately after curing, the yellowness index (YI_{120 hr}) measured after the light resistance test for about 120 hours, and the yellowness index change rate (ΔYI) are shown in Tables 3 and 4 below. The yellowness index change rate was calculated using the formula below.

ΔYI=YI_{120 hr}−YI_{0 hr}

TABLE 3

| | | Example | Example | Example | Example | Example | Example | Example | Example | Example | Example |
|---|---|---|---|---|---|---|---|---|---|---|---|
| Evaluation | | 1 | 2 | 3 | 4 | 5 | 6 | 7 | 8 | 9 | 10 |
| Shear viscosity | | 11 | 10 | 10 | 9 | 10 | 10 | 10 | 14 | 11 | 7 |
| (mPa · s) (30 °C) | | | | | | | | | | | |
| Curability | | o | o | o | o | o | o | o | o | o | o |
| 3PB strength (N) | | 44 | 48 | 50 | 46 | 53 | 48 | 50 | 37 | 45 | 40 |
| (30 °C) | | | | | | | | | | | |
| 180° peel strength | | 3000 | 1800 | 3800 | 2400 | 3600 | 3200 | 3300 | 3100 | 3100 | 2200 |
| (gf/25 mm) (25 °C) | | | | | | | | | | | |
| YI | Initial | 1.1 | 0.9 | 1.1 | 0.7 | 0.5 | 0.5 | 0.5 | 0.9 | 1 | 0.7 |
| | After 120 | 0.3 | 0.6 | 0.4 | 0.3 | 0.4 | 0.3 | 0.1 | 0.3 | 0.7 | 0.6 |
| | hours | | | | | | | | | | |
| | Change | −0.8 | −0.3 | −0.7 | −0.4 | −0.1 | −0.2 | −0.4 | −0.6 | −0.3 | −0.1 |

TABLE 4

| | | Compar- | Compar- | Compar- | Compar- | Compar- | Compar- | Compar- |
|---|---|---|---|---|---|---|---|---|
| | | ative | ative | ative | ative | ative | ative | ative |
| | | Example | Example | Example | Example | Example | Example | Example |
| Evaluation | | 1 | 2 | 3 | 4 | 5 | 6 | 7 |
| Shear viscosity | | 9 | 6 | 9 | 7 | 7 | 10 | >100 |
| (mPa · s) (30 °C) | | | | | | | | |
| Curability | | x | o | x | o | o | o | — |
| 3PB strength (N) | | — | 34 | — | 42 | 6 | 17 | — |
| (30 °C) | | | | | | | | |
| 180° peel strength | | — | 2200 | — | 3000 | 0 | 1800 | — |
| (gf/25 mm) (25 °C) | | | | | | | | |
| YI | Initial | — | 9.6 | — | 0.5 | 3 | 0.9 | 0 |
| | After 120 | — | 1.8 | — | 2.2 | 2.3 | 0.8 | 0.5 |
| | hours | | | | | | | |
| | Change | — | −7.8 | — | 1.7 | −0.7 | −0.1 | 0.5 |

Referring to the results in Tables 3 and 4, the resin compositions of the Examples had a viscosity of about 50 mPa·s or less measured at about 25 °C, a 3PB strength of about 35 N or more measured at about 30 °C after curing, and a 180° peel strength of about 1500 gf/25 mm or more measured at about 25 °C. For example, the low viscosity results in excellent dischargeability and excellent adhesion after curing. Also, excellent curability and light resistance were confirmed.

Compared to the Examples, the resin composition of Comparative Example 1 contained a compound that did not match the first compound, resulting in poor curability and preventing sample production.

The resin composition of Comparative Example 2 contained a compound that did not match the first compound, resulting in poor light resistance.

The resin composition of Comparative Example 3 contained an excessive amount of the first compound, resulting in poor curability and preventing sample production, as in Comparative Example 1.

The resin composition of Comparative Example 4, which did not contain the first compound, exhibited poor light resistance.

The resin composition of Comparative Example 5, which did not contain a double bond conjugated with a carbonyl group and contained at least one non-conjugated alkene group, used a first compound with an excessively or substantially high molecular weight, resulting in poor adhesion and light resistance. This is thought to be due to the high molecular weight, resulting in poor miscibility with a (meth)acrylate monomer and a urethane (meth)acrylate oligomer.

The resin composition of Comparative Example 6, which contained a compound did not match the first compound, exhibited poor adhesion.

The resin composition of Comparative Example 7, which contained an excessive amount of the urethane (meth)acrylate oligomer, exhibited excessive viscosity, resulting in poor dischargeability and preventing sample production.

The resin composition of one or more embodiments may exhibit low viscosity before curing and high adhesion and excellent or suitable light resistance after curing.

The adhesive member formed or made from the resin composition of one or more embodiments may exhibit excellent or suitable adhesion reliability and excellent or suitable light resistance.

The electronic apparatus of one or more embodiments may include the adhesive member formed or made from the resin composition of one or more embodiments and may exhibit excellent or suitable reliability and excellent or suitable display quality.

The resin composition of one or more embodiments may have low viscosity before curing and exhibit high adhesive strength and excellent or suitable light resistance after curing.

The adhesive member of one or more embodiments may exhibit excellent or suitable adhesion reliability and excellent or suitable light resistance.

The electronic apparatus of one or more embodiments may include the adhesive member of one or more embodiments and may exhibit excellent or suitable reliability and excellent or suitable display quality.

Although one or more embodiments of the present disclosure have been described, those skilled in the art or those of ordinary skill in the art will understand that one or more suitable modifications and changes can be made to the embodiments within the scope that does not depart from the spirit and scope of the present disclosure. Accordingly, the scope of the present disclosure should not be limited to the embodiments as described in the detailed description of the present disclosure, but should be determined by the appended claims and equivalents thereof.

What is claimed is:

1. A resin composition comprising:
a monofunctional (meth)acrylate monomer;
a urethane (meth)acrylate oligomer;
a first compound which does not comprise a double bond conjugated with a carbonyl group and comprises at least one alkene group, the alkene group being a non-conjugated alkene group; and
a photopolymerization initiator,
wherein the content of the urethane (meth)acrylate oligomer is in a range of 1 wt % to 30 wt % based on a total of 100 wt % of the resin composition,
a weight average molecular weight of the first compound is in a range of 28 g/mol to 2,500 g/mol, and
the content of the first compound is in a range of 0.1 wt % to 15 wt % based on a total of 100 wt % of the resin composition.

2. The resin composition as claimed in claim 1, wherein a shear viscosity as measured by a JIS Z 8803 method at 30 °C is in a range of 8 mPa·s to 50 mPa·s.

3. The resin composition as claimed in claim 1, wherein the first compound comprises at least one selected from among a pinene derivative, a rosin derivative, polybutadiene, limonene, a cholesterol derivative, and diprenyl glycerin ether.

4. The resin composition as claimed in claim 3, wherein the pinene derivative comprises at least one selected from among (1S)-(−)-α-pinene and α-terpineol.

5. The resin composition as claimed in claim 3, wherein the rosin derivative comprises dihydroabietic acid.

6. The resin composition as claimed in claim 1, wherein the monofunctional (meth)acrylate monomer comprises at least one selected from among 4-hydroxybutyl acrylate, tetrahydrofurfuryl acrylate, dodecyl acrylate, 2-methoxyethyl acrylate, ethyl acrylate, isobornyl acrylate, and isodecyl acrylate.

7. The resin composition as claimed in claim 1, wherein the content of the monofunctional (meth)acrylate monomer is in a range of 67 wt % to 95 wt % based on a total of 100 wt % of the resin composition.

8. The resin composition as claimed in claim 1, wherein a weight average molecular weight of the urethane (meth)acrylate oligomer is in a range of 3,000 g/mol to 50,000 g/mol.

9. The resin composition as claimed in claim 1, further comprising a silane coupling agent.

10. The resin composition as claimed in claim 1, wherein a yellowness index measured immediately after photocuring under conditions of integrated UV radiation dose in the atmosphere in a range of 1600 mJ/cm² to 2000 mJ/cm² is in a range of 0.1 to 1.5.

11. The resin composition as claimed in claim 1, wherein, after photocuring, a yellowness index measured after exposure for 120 hours under conditions of 0.4 W/m² of a light intensity at 340 nm and 50 °C using a xenon arc lamp is in a range of 0.1 to 1.5.

12. The resin composition as claimed in claim 1, wherein a difference between
a yellowness index measured immediately after photocuring under conditions of integrated UV radiation dose in the atmosphere in a range of 1600 mJ/cm² to 2000 mJ/cm²; and
a yellowness index measured after the photocuring and after exposure for 120 hours under conditions of 0.4 W/m² of a light quantity at 340 nm and 50 °C using a xenon arc lamp,
is in a range of −1.0 to 1.0.

13. The resin composition as claimed in claim 1, wherein the resin composition is provided by an inkjet printing method or a dispensing method.

14. An adhesive member comprising a polymer derived from a resin composition, wherein:
the resin composition comprises:
a monofunctional (meth)acrylate monomer;
a urethane (meth)acrylate oligomer;
a first compound which does not comprise a double bond conjugated with a carbonyl group and comprises at least one alkene group, the alkene group being a non-conjugated alkene group; and
a photopolymerization initiator,
the content of the urethane (meth)acrylate oligomer is in a range of 1 wt % to 30 wt % based on a total of 100 wt % of the resin composition,
a weight average molecular weight of the first compound is in a range of 28 g/mol to 2,500 g/mol, and
the content of the first compound is in a range of 0.1 wt % to 15 wt % based on a total of 100 wt % of the resin composition.

15. The adhesive member as claimed in claim 14, wherein a shear viscosity as measured by a JIS Z 8803 method at 30 °C is in a range of 8 mPa·s to 50 mPa·s.

16. The adhesive member as claimed in claim 14, wherein three-point bending strength measured at 30 °C is in a range of 35 N to 60 N.

17. An electronic apparatus comprising:
a display device to provide images; and
at least one adhesive member provided in the display device and comprising a polymer derived from a resin composition, wherein,
the resin composition comprises:
a monofunctional (meth)acrylate monomer;
a urethane (meth)acrylate oligomer;
a first compound which does not comprise a double bond conjugated with a carbonyl group and comprises at least one alkene group, the alkene group being a non-conjugated alkene group; and
a photopolymerization initiator,
the content of the urethane (meth)acrylate oligomer is in a range of 1 wt % to 30 wt % based on a total of 100 wt % of the resin composition,
a weight average molecular weight of the first compound is in a range of 28 g/mol to 2,500 g/mol, and
the content of the first compound is in a range of 0.1 wt % to 15 wt % based on a total of 100 wt % of the resin composition.

18. The electronic apparatus as claimed in claim 17, wherein:
the display device comprises a display module and a window; and
the at least one adhesive member is between the display module and the window.

19. The electronic apparatus as claimed in claim 18, wherein:
the window comprises a base layer and a printed layer provided between the at least one adhesive member and the base layer; and
the resin composition on one side of the display module or one side of the window is cured by light transmitted through the printed layer to provide the at least one adhesive member.

20. The electronic apparatus as claimed in claim 17, wherein the display device comprises a display module, a processor, a memory, and a power module.
